(19) United States
(12) Patent Application Publication
(10) Pub. No.: US 2026/0282893 A1
(43) Pub. Date: Sep. 17, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: I-Che LEE, Taipei City (TW); Pin-Ju CHEN, Hsinchu City (TW); Wei-Gang CHIU, New Taipei City (TW); Yen-Chieh HUANG, Changhua County (TW); Huai-Ying HUANG, New Taipei City (TW); Kai-Wen CHENG, Taichung City (TW); Yu-Ming LIN, Hsinchu City (TW)

(21) Appl. No.: 19/079,615

(22) Filed: Mar. 14, 2025

(51) Int. Cl. H01L 23/522; H01L 23/528; H10D 1/68; H10D 84/83

(52) U.S. Cl. CPC H10W 20/496; H10D 1/714; H10D 1/716; H10D 84/832; H10W 20/43

(57) ABSTRACT

A capacitor structure included in a semiconductor device may include one or more electrode layers that contain materials that have low hydrogen absorption properties to achieve a low concentration of hydrogen in the capacitor structure. These materials enable the capacitor structure to be formed by low-temperature processes that are compatible with layers and/or structures of the semiconductor device, while enabling fast charging and discharging speeds to be achieved for the capacitor structure. Additionally and/or alternatively, one or more of the electrode layers of the capacitor structure may contain metal materials that have a high band gap, which reduces the likelihood of (and/or amount of) charge carrier tunneling. This enables a low current leakage to be achieved for the capacitor structure, which enables the capacitor structure to retain charge for longer durations with fewer charge refreshes (which reduces power consumption of the semiconductor device).

### BACKGROUND

A capacitor structure, such as a deep trench capacitor (DTC) structure, may include a metal-insulator-metal (MIM) structure in which an insulator layer is sandwiched between two conductive electrode layers. Various types of semiconductor devices may include one or more capacitor structures, such as an image sensor device, a radio frequency (RF) device, a memory device (e.g., a dynamic random access memory (DRAM) device), a logic device, a processor, a system on chip (SoC), and/or an integrated passive device (IPD), among other examples.

In a semiconductor device, a capacitor structure may be included in an interconnect layer (e.g., a backend region) of the semiconductor device. The capacitor structure may extend through a plurality of dielectric layers in the interconnect layer and may be electrically coupled to one or more conductive structures in the interconnect layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of a portion of an example semiconductor device described herein.

FIGS. 2A-2C are diagrams of an example implementation of charging and discharging operations of a capacitor structure described herein.

FIGS. 3A-3C are diagrams of an example implementation of charging and discharging operations of a capacitor structure described herein.

FIGS. 4A-4K are diagrams of an example implementation of forming a semiconductor device described herein.

FIGS. 5A-5F are diagrams of example implementations of electrode layer combinations for a capacitor structure described herein.

FIGS. 6A-6E are diagrams of example implementations of structural arrangements for a capacitor structure described herein.

FIG. 7 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a capacitor structure may be formed in an interconnect layer of a semiconductor device using backend processing techniques that are compatible with the thermal budget of layers and/or structures formed in other regions of the semiconductor device such as a device layer (e.g., a frontend region). Some layers and/or structures formed of metal silicides and metals such as copper (Cu) may be susceptible to degradation when subjected to high-temperature processing, which may result in material diffusion that may result in performance impacts such as increased current leakage in the semiconductor device.

However, some layers of the capacitor structure may be susceptible to hydrogen (H) contamination if low-temperature processes are used to form the capacitor structure. These low-temperature processes may be ineffective in driving out hydrogen from the layers of the capacitor structure. Hydrogen that is retained in the capacitor structure may result in charge trapping in the capacitor structure, which may cause increased charging and discharging times for the capacitor structure.

Additionally and/or alternatively, the electrode layers of the capacitor structure may be formed of metal-containing materials that are prone to current leakage. For example, titanium-containing materials may be susceptible to current leakage from the electrode layers, which may reduce charge retention performance for the capacitor structure. The reduced charge retention for the capacitor structure may result in increased power consumption in use cases in which the capacitor structure is implemented as a memory structure in that increased charge refreshes may be needed to retain data in the capacitor structure.

In some implementations described herein, a capacitor structure included in a semiconductor device (e.g., an interconnect layer of a semiconductor device) may include one or more electrode layers that contain materials that have low hydrogen absorption properties to achieve a low concentration of hydrogen in the capacitor structure. These materials enable the capacitor structure to be formed by low-temperature processes that are compatible with layers and/or structures of the semiconductor device, while enabling fast charging and discharging speeds to be achieved for the capacitor structure.

Additionally and/or alternatively, one or more of the electrode layers of the capacitor structure may contain metal materials for tuning the band gap of the electrode layer(s). For example, the metal materials of the electrode layer(s) may have a high band gap, which reduces the likelihood of (and/or amount of) charge carrier tunneling. This enables a low current leakage to be achieved for the capacitor structure, which enables the capacitor structure to retain a charge for longer durations with fewer charge refreshes (which reduces power consumption of the semiconductor device).

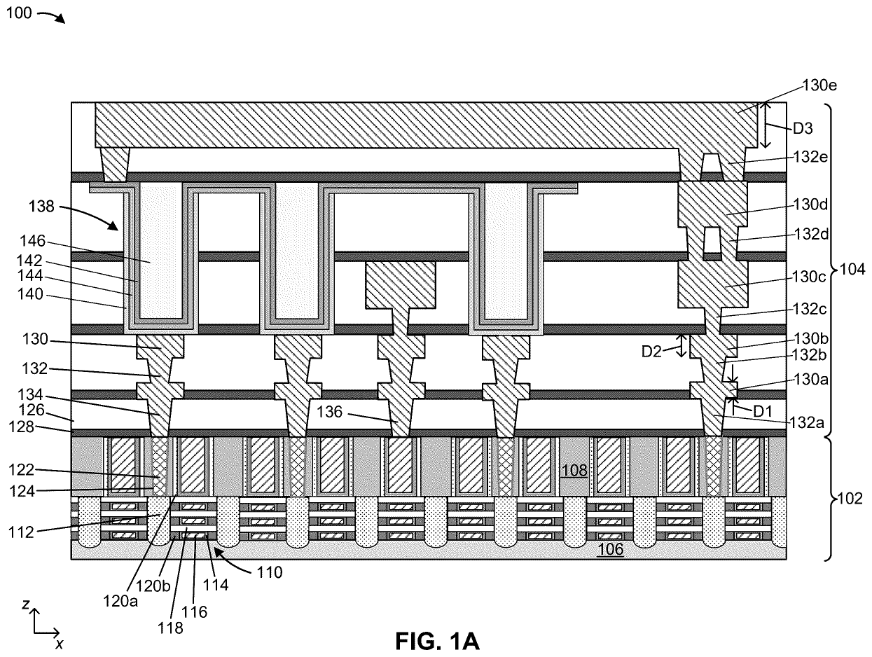

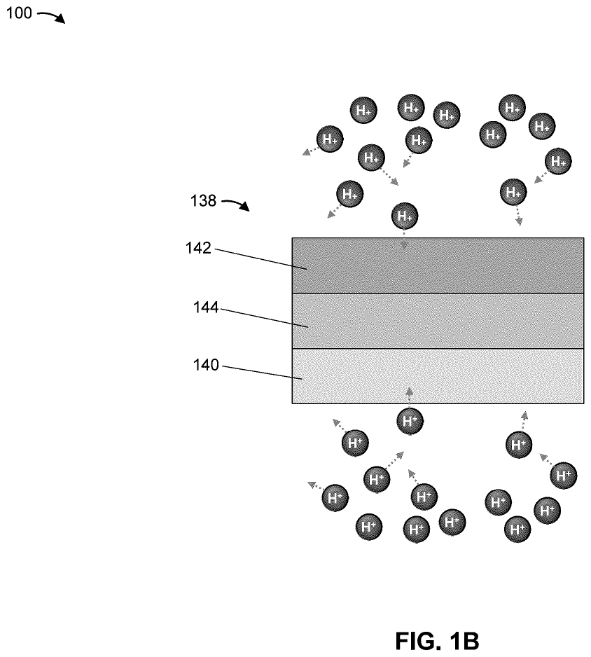

FIGS. 1A and 1B are diagrams of a portion of an example semiconductor device 100 described herein. The semiconductor device 100 may include a system on chip (SoC) device, a logic device such as a central processing unit (CPU) or a graphics processing unit (GPU), a memory device (e.g., a high bandwidth memory (HBM) device), a panel driver device, an integrated circuit (IC) driver, a radio frequency (RF) power amplifier, a display driver IC (DDIC), and/or another type of semiconductor device.

As shown in FIG. 1A, the semiconductor device 100 may include a device layer 102 and an interconnect layer 104 above the device layer 102 in a z-direction in the semiconductor device 100. The device layer 102 includes a substrate layer 106. The substrate layer 106 may correspond to a portion of a semiconductor wafer on which the semiconductor device 100 is formed. The substrate layer 106 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate layer 106 may extend in an x-direction and/or in a y-direction in the semiconductor device 100.

A dielectric layer 108 is included over the substrate layer 106. The dielectric layer 108 includes an interlayer dielectric (ILD) layer (e.g., an ILD0 layer), an etch stop layer (ESL), and/or another type of dielectric layer. The dielectric layer 108 includes dielectric material(s) that enable various portions of the substrate layer 106 to be selectively etched or protected from etching, and/or may electrically isolate integrated circuit devices 110 in the device layer 102. The dielectric layer 108 includes a silicon nitride (SiₓN_{y}), an oxide (e.g., a silicon oxide (SiOₓ) and/or another oxide material), and/or another type of dielectric material. The dielectric layer 108 may extend in the x-direction and/or in a y-direction in the semiconductor device 100.

The integrated circuit devices 110 may be included in and/or on the substrate layer 106, and/or in in the dielectric layer 108 in the device layer 102 of the semiconductor device 100. The integrated circuit devices 110 include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of semiconductor devices.

An integrated circuit device 110 may include a plurality of source/drain regions 112 that are grown and/or otherwise formed on and/or around portions of the substrate layer 106. “Source/drain region(s)” may refer to a source or a drain, individually or collectively, dependent upon the context. The source/drain regions 112 may be formed by epitaxially growing doped semiconductor regions and/or by another semiconductor process. In some implementations, the source/drain regions 112 are formed in recessed portions in the substrate layer 106. The recessed portions may be formed by strained source/drain (SSD) etching of the substrate layer 106 and/or another type etching operation. In some implementations, the source/drain regions 112 are formed in recesses that are formed in an alternating stack of channel layers and sacrificial layers (e.g., silicon germanium (SiGe)) layers.

An integrated circuit device 110 may further include a gate dielectric layer 114 between a gate structure 116 and channel layers 118 of the integrated circuit device 110. The channel layers 118 may extend between the source/drain regions 112 of the integrated circuit device 110, and gate dielectric layer 114 and the gate structure 116 may wrap around two or more sides of the channel layers 118. In some implementations, the gate dielectric layer 114 and the gate structure 116 wrap around all four sides of the channel layers 118. In these implementations, the integrated circuit device 110 may be referred to as a nanostructure transistor such as a GAA transistor.

The channel layers 118 may include nanoscale layers of semiconductor material, such as silicon (Si), silicon germanium (SiGe), and/or doped silicon, among other examples. The channel layers 118 may be formed from silicon nanosheets that are formed as part of a nanosheet stack above the substrate layer 106.

In some implementations, the gate dielectric layer 114 includes a low dielectric constant (low-k) dielectric material such as silicon oxide (SiOₓ). In some implementations, the gate dielectric layer 114 includes a high dielectric constant (high-k) dielectric material such as hafnium oxide (HfOₓ).

The gate structure 116 may be located laterally between the source/drain regions 112. In some implementations, the gate structure 116 is formed of a polysilicon material. In these implementations, the polysilicon material may be doped with one or more types of dopants (e.g., p-type dopants, n-type dopants) to tune a work function of the gate structure 116.

In some implementations, the gate structure 116 is formed of one or more metal materials (e.g., tungsten (W), titanium (Ti), cobalt (Co), and/or another metal). In these implementations, the gate structure 116 may include one or more work function metal layers (e.g., p-type metal layers, n-type metal layers) for tuning the work function of the gate structure 116. The work function metal layer(s) may be included between the gate dielectric layer 114 and the gate structure 116.

A p-type work function metal layer may include one or more p-type metals, such as tungsten (W), cobalt (Co), titanium nitride (TiN), tungsten nitride (WN), and/or another metal having a work function that is greater than approximately 4.7 electron volts (eV), among other examples. A p-type work function metal layer may be included to tune the work function of the gate structure 116 such that the work function is adjusted close to the valence band of the material of the channel layers 118.

An n-type work function metal layer may include one or more metal materials that tune or adjust the work function of the gate structure 116 near the conduction band of the material of the channel layers 118 of the semiconductor device 100. In some implementations, an n-type work function metal layer may include titanium aluminum (TiAl). In some implementations, an n-type work function metal layer includes titanium aluminum carbon (TiAlC). In some implementations, an n-type work function metal layer another aluminum-containing metal. In some implementations, another n-type metal material is included in an n-type work function metal layer.

Various spacers may be included in the integrated circuit devices 110. For example, sidewall spacers 120a may be included on the sidewalls of the gate structure 116 to provide electrical isolation for the gate structure 116, among other examples. In some implementations, the sidewall spacers 120a are in contact with the gate dielectric layer 114. In some implementations, the sidewall spacers 120a are in contact with the work function metal layer. The sidewall spacers 120a may include a silicon oxide (SiOₓ), a silicon nitride (SiₓN_{y}), a silicon oxycarbide (SiOC), a silicon oxycarbonitride (SiOCN), and/or another suitable material.

As another example, inner spacers 120b may be included laterally between the gate structure 116 and the source/drain regions 112 of an integrated circuit device 110. The inner spacer 120b may be included to reduce parasitic capacitance in the integrated circuit device 110 and to protect the source/drain regions 112 from being etched in a nanosheet release operation to remove sacrificial layers between the channel layers 118. The inner spacers 122b may include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

The source/drain regions 112 are electrically coupled and/or physically coupled with source/drain contact structures 122. The source/drain contact structures 122 may include contact vias, contact plugs, and/or another type of contact structures that electrically connect the source/drain regions 112 of the integrated circuit devices 110 with the interconnect layer 104 of the semiconductor device 100. The source/drain contact structures 122 include cobalt (Co), ruthenium (Ru), tungsten (W), molybdenum (Mo), copper (Cu), and/or another electrically conductive material or metal material. One or more liner layers 124 may be included on sidewalls of the source/drain contact structures 122. The liner layer(s) 124 may include a barrier layer that is included to prevent or minimize diffusion of materials from the source/drain contact structures 122 to the surrounding dielectric layers, an adhesion layer or glue layer that is included to promote adhesion between the source/drain contact structures 122 and the surrounding dielectric layers, and/or another type of liner. Examples of materials for the liner layer(s) 124 include titanium nitride (TiN), tantalum nitride (TaN), and/or another suitable liner material.

The interconnect layer 104 of the semiconductor device 100 is included above the device layer 102 and above the integrated circuit devices 110 in the z-direction in the semiconductor device 100. The interconnect layer 104 includes a plurality of dielectric layers that are arranged in a direction (e.g., the z-direction) that is approximately perpendicular to the substrate layer 106. The dielectric layers may include ILD layers 126 and ESLs 128 that are arranged in an alternating manner in the z-direction. The ILD layers 126 and the ESLs 128 may extend in the x-direction and/or in the y-direction in the semiconductor device 100.

The ILD layers 126 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 126 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 128 may each include a silicon nitride (SiₓN_{y}), silicon carbide (SiC), silicon oxynitride (SiON), and/or another suitable dielectric material. In some implementations, an ILD layer 126 and an ESL 128 include different dielectric materials to provide etch selectivity to enable various structures to be formed in the interconnect layer 104.

The interconnect layer 104 may further include a plurality of layers of conductive structures in the dielectric layers (e.g., the ILD layers 126 and the ESLs 128) of the interconnect layer 104. The conductive structures in the interconnect layer 104 may be interconnected to enable signals and/or power to be distributed throughout the semiconductor device 100 through the interconnect layer 104. The conductive structures include a combination of metallization structures 130 and interconnect structures 132. The metallization structures 130 may include trenches, conductive traces, and/or other types of conductive structures that primarily extend in the x-direction and/or in the y-direction in the interconnect layer 104. The interconnect structures 132 may include vias, plugs, conductive columns, and/or other types of conductive structures that primarily extend in the z-direction in the semiconductor device. In some implementations, a conductive structure in the interconnect layer 104 includes a dual damascene structure, which includes a combination of a metallization structure 130 and an interconnect structure 132.

The metallization structures 130 and the interconnect structures 132 may each include one or more electrically conductive materials such as tungsten (W), cobalt (Co), ruthenium (Ru), molybdenum (Mo), titanium (Ti), aluminum (Al), copper (Cu), gold (Au), and/or a combination thereof, among other examples of electrically conductive materials. In some implementations, one or more liner layers are included between the metallization structures 130 and/or the interconnect structures 132 and the surrounding dielectric layers in the interconnect layer 104. The one or more liner layers may include barrier liners, adhesion liners, and/or another type of liners. Examples of materials for the one or more liners include tantalum nitride (TaN) and/or titanium nitride (TiN), among other examples.

In some implementations, the metallization structures 130 and the interconnect structures 132 of the interconnect layer 104 may be arranged in a vertical manner (e.g., in the z-direction). In other words, a plurality of stacked metallization structures 130 and interconnect structures 132 may extend between the device layer 102 and a top of the interconnect layer 104 to facilitate electrical signals and/or power to be routed between the device layer 102 and connection structures (not shown) of the semiconductor device 100.

The plurality of stacked metallization structures 130 may be arranged in layers that may be referred to as M-layers, and the plurality of stacked interconnect structures 132 may be arranged in layers that may be referred to as V-layers. A bottom-most layer of interconnect structures 132a in the interconnect layer 104 may be referred to as a V0 layer, and may include source/drain interconnect structures 134 that are electrically coupled and/or physically coupled to the source/drain contact structures 122 of one or more integrated circuit devices 110, and gate interconnect structures 136 that are electrically coupled and/or physically coupled to the gate structures 116 of one or more integrated circuit devices 110. The source/drain interconnect structures 134 are referred to source/drain vias (VDs), and the gate interconnect structures 136 are referred to as gate vias (VGs). In some implementations, gate contacts (not shown) are included between the gate structures 116 and the gate interconnect structures 136.

A layer of metallization structures 130a may be referred to as a metal-0 (M0) layer, and may be located above the layer of interconnect structures 132a (including the source/drain interconnect structures 134 and the gate interconnect structures 136) in the interconnect layer 104. The metallization structures 130a in the M0 layer may be electrically coupled and/or physically coupled with the source/drain interconnect structures 134 and/or the gate interconnect structures 136.

Additional layers of conductive structures may be arranged in a similar manner in the interconnect layer 104. For example, a layer of interconnect structures 132b may be referred to as a via-1 (V1) layer that is located above and electrically coupled and/or physically coupled to the layer of metallization structures 130a in the M0 layer. A layer of metallization structures 130b may be referred to as a metal-1 (M1) layer that is located above and electrically coupled and/or physically coupled to the layer of interconnect structures 132b in the V1 layer. A layer of interconnect structures 132c may be referred to as a via-1 (V2) layer that is located above and electrically coupled and/or physically coupled to the layer of metallization structures 130b in the M1 layer. A layer of metallization structures 130c may be referred to as a metal-2 (M2) layer that is located above and electrically coupled and/or physically coupled to the layer of interconnect structures 132c in the V2 layer. A layer of interconnect structures 132d may be referred to as a via-3 (V3) layer that is located above and electrically coupled and/or physically coupled to the layer of metallization structures 130c in the M2 layer. A layer of metallization structures 130d may be referred to as a metal-3 (M3) layer that is located above and electrically coupled and/or physically coupled to the layer of interconnect structures 132d in the V3 layer. A layer of interconnect structures 132e may be referred to as a via-4 (V4) layer that is located above and electrically coupled and/or physically coupled to the layer of metallization structures 130d in the M3 layer. A layer of metallization structures 130e may be referred to as a metal-4 (M4) layer that is located above and electrically coupled and/or physically coupled to the layer of interconnect structures 132e in the V4 layer. In some implementations, the interconnect layer 104 includes a different quantity of layers of metallization structures 130 and/or a different quantity of layers of interconnect structures 132 than the quantities shown in FIG. 1A.

As further shown in FIG. 1A, the sizes metallization structures 130 of the layers of metallization structures 130 may be greater the further up in the interconnect layer 104 the layers of metallization structures 130 are located. For example, the thickness of the metallization structures 130a (e.g., in the M0 layer) may have a first thickness (indicated in FIG. 1A as a dimension D1), the thickness of the metallization structures 130b (e.g., in the M1 layer) may have a second thickness (indicated in FIG. 1A as a dimension D2), and the second thickness may be greater than the first thickness. As another example, the thickness of the metallization structures 130a (e.g., in the M0 layer) may have a first thickness (indicated in FIG. 1A as a dimension D1), the thickness of the metallization structures 130e (e.g., in the M4 layer) may have a second thickness (indicated in FIG. 1A as a dimension D3), and the second thickness may be greater than the first thickness. As another example, the thickness of the metallization structures 130b (e.g., in the M1 layer) may have a first thickness (indicated in FIG. 1A as a dimension D2), the thickness of the metallization structures 130e (e.g., in the M4 layer) may have a second thickness (indicated in FIG. 1A as a dimension D3), and the second thickness may be greater than the first thickness.

The increasing thickness of the layers of metallization structures 130 in the interconnect layer 104 enables higher voltage and/or higher current signals and/or power to be distributed closer to the top of the interconnect layer 104. As signals propagate further down in the interconnect layer 104, voltage and/or power of the signals is reduced to achieve power efficiency and/or to enable a higher density of metallization structures 130 to be arranged at the bottom of the interconnect layer 104.

As further shown in FIG. 1A, the semiconductor device 100 may include one or more capacitor structures 138 in the interconnect layer 104. A capacitor structure 138 may include a trench capacitor structure that is included in and extends through one or more of the dielectric layers (e.g., one or more of the ILD layers 126, one or more of the ESLs 128) of the interconnect layer 104. The capacitor structure 138 may include a deep trench capacitor (DTC) structure in that the capacitor structure 138 has a high aspect ratio between a vertical (z-direction) height of the capacitor structure 138 and a lateral (x-direction) width of the capacitor structure 138. For example, the aspect ratio of the capacitor structure 138 may be greater than approximately 10:1, and in some implementations is included in a range of approximately 18:1 to approximately 55:1. However, other values and ranges for the aspect ratio for the capacitor structure 138 are within the scope of the present disclosure.

As shown in FIG. 1A, the capacitor structure 138 may include a plurality of conformal layers, including a bottom electrode layer 140, a top electrode layer 142, and an insulator layer 144 sandwiched between the bottom electrode layer 140 and the top electrode layer 142.

The bottom electrode layer 140, the insulator layer 144, and the top electrode layer 142 correspond to an MIM stack of the capacitor structure 138. Thus, the capacitor structure 138 may also be referred to as an MIM capacitor structure. The bottom electrode layer 140 (also referred to as a capacitor bottom metal (CBM)) and the top electrode layer 142 (also referred to as a capacitor top metal (CTM)) may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), tantalum (Ta), aluminum (Al), copper (Cu), gold (Au), titanium nitride (TiN), and/or tantalum nitride (TaN), among other examples. In some implementations, the bottom electrode layer 140 and the top electrode layer 142 include the same material or the same material composition. In some implementations, the bottom electrode layer 140 and the top electrode layer 142 include different materials or different material compositions.

The insulator layer 144 may include one or more electrically insulating materials. In some implementations, the insulator layer 144 includes one or more low-k dielectric materials such as silicon oxide (SiOₓ such as SiO₂). Additionally and/or alternatively, the insulator layer 144 may include one or more high-k dielectric materials such as zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), and/or hafnium oxide (HfOₓ such as HfO₂), among other examples. In some implementations, the insulator layer 144 is a multiple-layer stack that includes a plurality of dielectric layers. For example, the insulator layer 144 may include a ZrO₂/Al₂O₃/ZrO₂ (ZAZ) layer stack.

In some implementations, the capacitor structure 138 includes a single trench segment in which the bottom electrode layer 140, top electrode layer 142, and the insulator layer 144 may extend along the sidewalls and the bottom surface of a trench through the one or more dielectric layers of the interconnect layer 104. A dielectric filler 146 may fill in the remainder of the trench segment. However, in other implementations, the dielectric filler 146 is omitted. In some implementations, the capacitor structure 138 includes a plurality of trench segments. In some implementations, the bottom electrode layer 140, top electrode layer 142, and the insulator layer 144 may extend continuously through and between the trench segments. In some implementations, non-contiguous bottom electrode layers 140 are included in each of the trench segments, as shown in the example in FIG. 1A.

As further shown in FIG. 1A, the capacitor structure 138 may be electrically coupled and/or physically coupled to one or more conductive structures in the interconnect layer 104. In some implementations, the bottom electrode layer 140 of the capacitor structure 138 is located on and/or in electrical connection with a metallization structure 130, such as a metallization structure 130b (e.g., in the M1 layer). In these implementations, the bottom electrode layer 140 is electrically coupled to the metallization structure 130b at the bottom of the capacitor structure 138. In some implementations, a metallization structure 130, such as a metallization structure 130e (e.g., in the M4 layer) is located on and/or in electrical connection with the top electrode layer 142 of the capacitor structure 138. In these implementations, the top electrode layer 142 is electrically coupled to the metallization structure 130e at the top of the capacitor structure 138. However, other connection arrangements are within the scope of the present disclosure. For example, the bottom electrode layer 140 and the top electrode layer 142 may both be electrically coupled to metallization structures 130 at the top of the capacitor structure 138.

As shown in FIG. 1B, the bottom electrode layer 140 and/or the top electrode layer 142 of the capacitor structure 138 may include one or more metal materials that inhibit the absorption of hydrogen (H) in the capacitor structure 138. Various conductive structures (e.g., metallization structures 130, interconnect structures 132) in the interconnect layer 104 may contain copper (Cu) and/or other metal materials that are more readily absorb hydrogen than other metal materials. Accordingly, the bottom electrode layer 140 and/or the top electrode layer 142 may be formed metal material(s) that block hydrogen in the conductive structures from being absorbed into the insulator layer 144, which might otherwise result in charge trapping in the insulator layer 144. Charge trapping might otherwise form a leakage path through the insulator layer 144. Thus, the metal material(s) of the bottom electrode layer 140 and/or the top electrode layer 142 may enable a low current leakage to be achieved in the capacitor structure 138.

The metal material(s) of the bottom electrode layer 140 and/or the top electrode layer 142 may have a low hydrogen diffusion coefficient to promote the blocking of hydrogen diffusion. Metal materials that have low hydrogen diffusion coefficients, as used herein, may refer to metal materials that have hydrogen diffusion coefficients that are less than the hydrogen diffusion coefficient of titanium-containing materials such as titanium (Ti) and titanium nitride (TiN) at approximately the same temperature. Examples of such metal materials include various transition metals in groups 6 through 12 of the periodic table, such as ruthenium (Ru), tungsten (W), nickel (Ni), silver (Ag), and/or palladium (Pd), among other examples. In some implementations, the bottom electrode layer 140 and/or the top electrode layer 142 may include another metal material having a low hydrogen diffusion coefficient such as aluminum (Al).

These metal materials have crystal structures that have limited available interstitial sites through which hydrogen can diffuse, thereby limiting the ability of hydrogen to diffuse through the material. For example, ruthenium may have a hexagonal close-packed (hcp) crystal structure that has limited available interstitial sites through which hydrogen can diffuse. As another example, tungsten may have a body-centered cubic (bcc) crystal structure that has limited available interstitial sites through which hydrogen can diffuse.

In some implementations, the bottom electrode layer 140 and the top electrode layer 142 may each contain a metal material having a hydrogen diffusion coefficient that is less than the hydrogen diffusion coefficient of titanium. In these implementations, the bottom electrode layer 140 may block hydrogen from diffusing from conductive structures below the capacitor structure 138 into the insulator layer 144, and the top electrode layer 142 may block hydrogen from diffusing from conductive structures above the capacitor structure 138 into the insulator layer 144.

In some implementations, the bottom electrode layer 140 contains a metal material having a hydrogen diffusion coefficient that is less than the hydrogen diffusion coefficient of titanium, and the top electrode layer 142 contains a different metal material such as titanium (Ti). In these implementations the hydrogen diffusion coefficient of the metal material of the bottom electrode layer 140 may be less than the hydrogen diffusion coefficient of the metal material of the top electrode layer 142. In some implementations, the top electrode layer 142 contains a metal material having a hydrogen diffusion coefficient that is less than the hydrogen diffusion coefficient of titanium, and the bottom electrode layer 140 contains a different metal material such as titanium (Ti). In these implementations the hydrogen diffusion coefficient of the metal material of the bottom electrode layer 140 may be greater than the hydrogen diffusion coefficient of the metal material of the top electrode layer 142.

In some implementations, the bottom electrode layer 140 and the top electrode layer 142 contain the same metal material having a low hydrogen diffusion coefficient. For example, the bottom electrode layer 140 and the top electrode layer 142 both contain ruthenium (Ru). In some implementations, the bottom electrode layer 140 and the top electrode layer 142 contain different metal materials that each have a low hydrogen diffusion coefficient. For example, the bottom electrode layer 140 may contain tungsten (W) and the top electrode layer 142 may contain nickel (Ni).

Additionally and/or alternatively to the metal material(s) of the bottom electrode layer 140 and/or of the top electrode layer 142 having a low hydrogen diffusion coefficient, the metal material(s) of the bottom electrode layer 140 and/or of the top electrode layer 142 may have a high work function for tuning the operation speed and/or leakage performance for the capacitor structure 138. In particular, the metal material(s) of the bottom electrode layer 140 and/or of the top electrode layer 142 may have a work function that is greater than the work function of titanium (Ti). In other words, the metal material(s) of the bottom electrode layer 140 and/or of the top electrode layer 142 may have a work function that is greater than approximately 4.33. Examples of such metal materials include various transition metals in groups 6 through 12 of the periodic table, such as chromium (Cr), iron (Fe), cobalt (Co), copper (Cu), ruthenium (Ru), molybdenum (Mo), platinum (Pt), rhodium (Rh), tungsten (W), nickel (Ni), gold (Au), palladium (Pd), rhenium (Re), osmium (Os), iridium (Ir), and/or mercury (Hg), among other examples of metal materials that have work functions included in a range of approximately 4.5 electron volts (eV) to approximately 5.7 eV or greater.

The high work function of the metal material(s) of the metal material(s) of the bottom electrode layer 140 and/or of the top electrode layer 142 provides a greater band gap between the fermi energy level of the metal material and a vacuum energy level, and thus a higher barrier height between the top of the band gap of the insulator layer 144 and the fermi energy level of the metal material(s) of the bottom electrode layer 140 and/or of the top electrode layer 142. This higher barrier height enables charge carriers to be more reliably retained in the capacitor structure with reduced leakage through the insulator layer 144.

In some implementations, the bottom electrode layer 140 and/or of the top electrode layer 142 may contain a metal material having a low hydrogen diffusion coefficient and a high work function, such as ruthenium (Ru), tungsten (W), nickel (Ni), and/or palladium (Pd), among other examples. This enables the bottom electrode layer 140 and/or of the top electrode layer 142 to block the absorption of hydrogen and increase the operating speeds (e.g., the charging and/or discharging speeds) of the capacitor structure 138 without additional masking and etching processes.

In some implementations, the bottom electrode layer 140 and the top electrode layer 142 may each contain a metal material having a work function that is greater than the work function of titanium. In some implementations, the bottom electrode layer 140 contains a metal material having a work function that is greater than the work function of titanium, and the top electrode layer 142 contains a different metal material such as titanium (Ti). In these implementations the work function of the metal material of the bottom electrode layer 140 may be greater than the work function of the metal material of the top electrode layer 142. In some implementations, the top electrode layer 142 contains a metal material having a work function that is greater than the work function of titanium, and the bottom electrode layer 140 contains a different metal material such as titanium (Ti). In these implementations the work function of the metal material of the bottom electrode layer 140 may be less than the work function of the metal material of the top electrode layer 142.

In some implementations, the bottom electrode layer 140 and the top electrode layer 142 contain the same metal material having a high work function. For example, the bottom electrode layer 140 and the top electrode layer 142 both contain ruthenium (Ru). In some implementations, the bottom electrode layer 140 and the top electrode layer 142 contain different metal materials that each have a high work function. For example, the bottom electrode layer 140 may contain palladium (Pd) and the top electrode layer 142 may contain platinum (Pt).

As indicated above, FIGS. 1A and 1B are provided as an example. Other examples may differ from what is described with regard to FIGS. 1A and 1B.

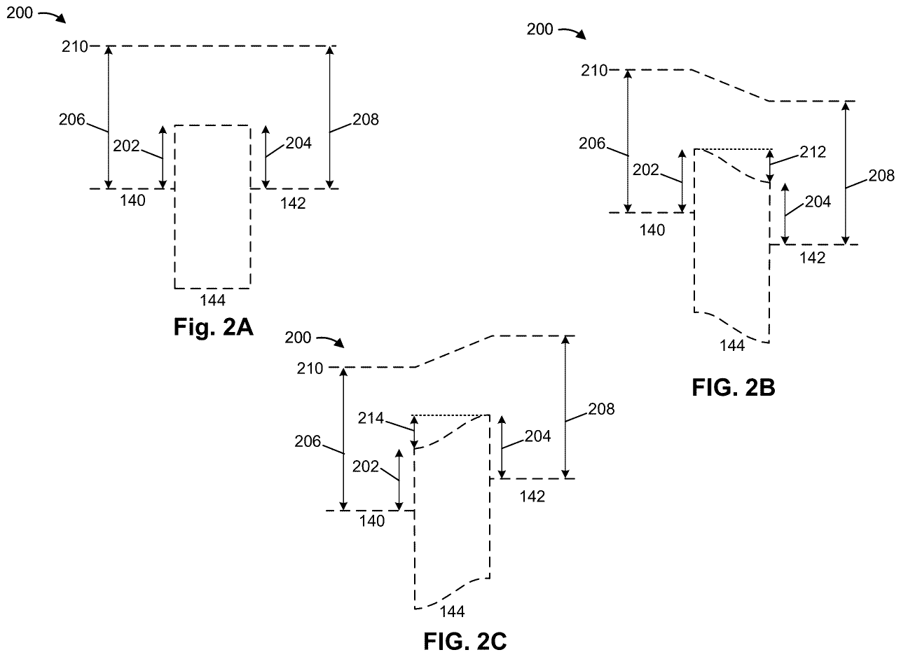

FIGS. 2A-2C are diagrams of an example implementation 200 of charging and discharging operations of a capacitor structure 138 described herein. In the example implementation 200, the bottom electrode layer 140 of the capacitor structure 138 and the top electrode layer 142 of the capacitor structure 138 each contain the same metal material having a high work function (e.g., a work function greater than the work function of titanium).

FIG. 2A illustrates a band diagram of the capacitor structure 138 without an electrical bias applied to the capacitor structure 138. As shown in FIG. 2A, since the bottom electrode layer 140 and the top electrode layer 142 contain the same metal material, barrier heights 202 and 204 respectively for the bottom electrode layer 140 and the top electrode layer 142 may be approximately equal. The barrier height 202 is the difference between the fermi energy level of the bottom electrode layer 140 and the top of the band gap for the insulator layer 144. The barrier height 204 is the difference between the fermi energy level of the bottom electrode layer 140 and the top of the band gap for the insulator layer 144. Moreover, the work functions 206 and 208 respectively of the bottom electrode layer 140 and the top electrode layer 142 (which are the differences between the respective fermi energy levels and a vacuum level 210) are approximately equal.

FIG. 2B illustrates the band diagram of the capacitor structure 138 with an electrical bias applied to the capacitor structure 138. As shown in FIG. 2B, the electrical bias applied to the capacitor structure 138 results in the occurrence of a potential 212 in the insulator layer 144, which in turn results in shifting in the vacuum level 210. In this configuration, the capacitor structure 138 may be charged so that charge carriers may be stored and retained in the bottom electrode layer 140 and in the top electrode layer 142. In particular, the potential 212 results in opposing charge carrier types (e.g., electrons and holes) being stored and retained in the bottom electrode layer 140 and in the top electrode layer 142.

FIG. 2C illustrates the band diagram of the capacitor structure 138 with an electrical bias applied to the capacitor structure 138. The electrical bias may have an opposite polarity relative to the electrical bias applied in FIG. 2B. As shown in FIG. 2C, the electrical bias applied to the capacitor structure 138 results in the occurrence of a potential 214 in the insulator layer 144, which in turn results in shifting in the vacuum level 210. In this configuration, the capacitor structure 138 may be discharged so that opposing charge carriers stored in the bottom electrode layer 140 and in the top electrode layer 142 recombine to release stored energy in the capacitor structure 138.

The high work function of the metal material of the bottom electrode layer 140 and of the top electrode layer 142 enable low leakage to be achieved in the charged state illustrated in FIG. 2B, which enables charge carriers to be retained in the bottom electrode layer 140 and in the top electrode layer 142 for longer durations between refreshes. This increases the energy efficiency and data retention reliability of the capacitor structure 138.

As indicated above, FIGS. 2A-2C are provided as examples. Other examples may differ from what is described with regard to FIGS. 2A-2C.

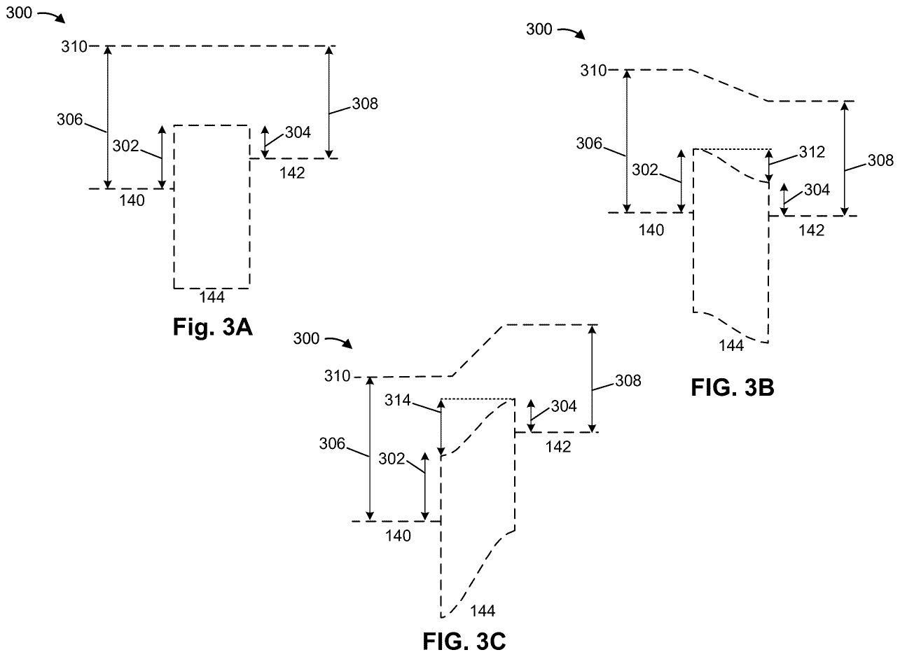

FIGS. 3A-3C are diagrams of an example implementation 300 of charging and discharging operations of a capacitor structure 138 described herein. In the example implementation 200, the bottom electrode layer 140 of the capacitor structure 138 and the top electrode layer 142 of the capacitor structure 138 contain different metal materials having different work functions.

FIG. 3A illustrates a band diagram of the capacitor structure 138 without an electrical bias applied to the capacitor structure 138. As shown in FIG. 3A, since the bottom electrode layer 140 and the top electrode layer 142 contain different metal materials, barrier heights 302 and 304 respectively for the bottom electrode layer 140 and the top electrode layer 142 are different. The barrier height 302 is the difference between the fermi energy level of the bottom electrode layer 140 and the top of the band gap for the insulator layer 144. The barrier height 304 is the difference between the fermi energy level of the bottom electrode layer 140 and the top of the band gap for the insulator layer 144. The work functions 306 and 308 respectively of the bottom electrode layer 140 and the top electrode layer 142 (which are the differences between the respective fermi energy levels and a vacuum level 310) are also different.

The bottom electrode layer 140 main contain a metal material having a greater work function 306 than the work function 308 of the top electrode layer 142. As a result, the barrier height between the fermi energy level of the bottom electrode layer 140 and the top of the insulator layer 144 may be greater than the barrier height between the fermi energy level of the top electrode layer 142 and the top of the insulator layer 144.

FIG. 3B illustrates the band diagram of the capacitor structure 138 with an electrical bias applied to the capacitor structure 138. As shown in FIG. 3B, the electrical bias applied to the capacitor structure 138 results in the occurrence of a potential 312 in the insulator layer 144, which in turn results in shifting in the vacuum level 310. In this configuration, the capacitor structure 138 may be charged so that charge carriers may be stored and retained in the bottom electrode layer 140 and in the top electrode layer 142. In particular, the potential 312 results in opposing charge carrier types (e.g., electrons and holes) being stored and retained in the bottom electrode layer 140 and in the top electrode layer 142.

FIG. 3C illustrates the band diagram of the capacitor structure 138 with an electrical bias applied to the capacitor structure 138. The electrical bias may have an opposite polarity relative to the electrical bias applied in FIG. 3B. As shown in FIG. 3C, the electrical bias applied to the capacitor structure 138 results in the occurrence of a potential 314 in the insulator layer 144, which in turn results in shifting in the vacuum level 310. In this configuration, the capacitor structure 138 may be discharged so that opposing charge carriers stored in the bottom electrode layer 140 and in the top electrode layer 142 recombine to release stored energy in the capacitor structure 138.

The higher work function of the metal material of the top electrode layer 142 enables low leakage to be achieved in the charged state illustrated in FIG. 3B, which enables charge carriers to be retained in the bottom electrode layer 140 and in the top electrode layer 142 for longer durations between refreshes. This increases the energy efficiency and data retention reliability of the capacitor structure 138. Moreover, the lower work function of the metal material of the top electrode layer 142 enables the capacitor structure 138 to be quickly discharged at lower electrical biases in FIG. 3C. This increases the operating speed of the capacitor structure 138.

As indicated above, FIGS. 3A-3C are provided as examples. Other examples may differ from what is described with regard to FIGS. 3A-3C.

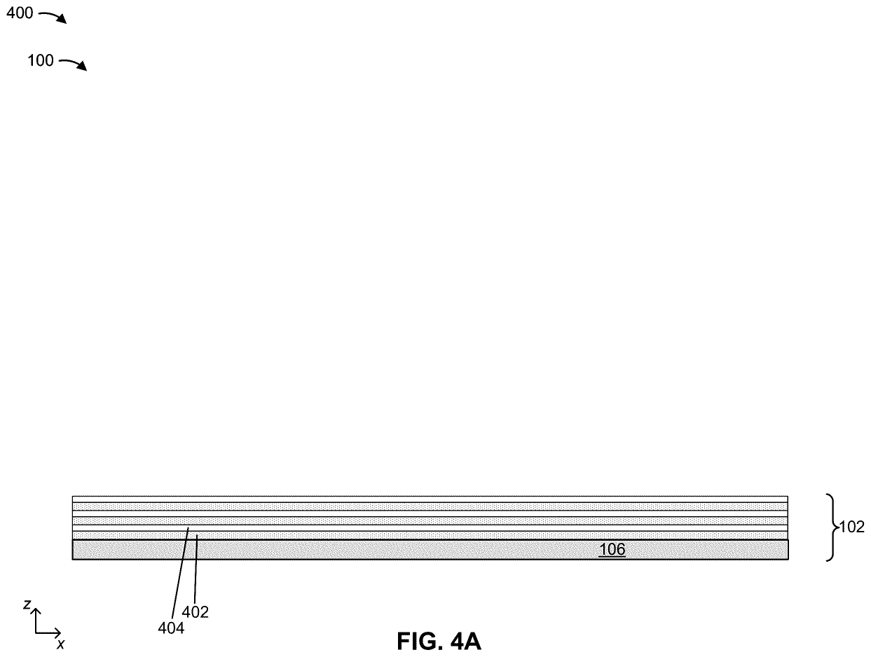

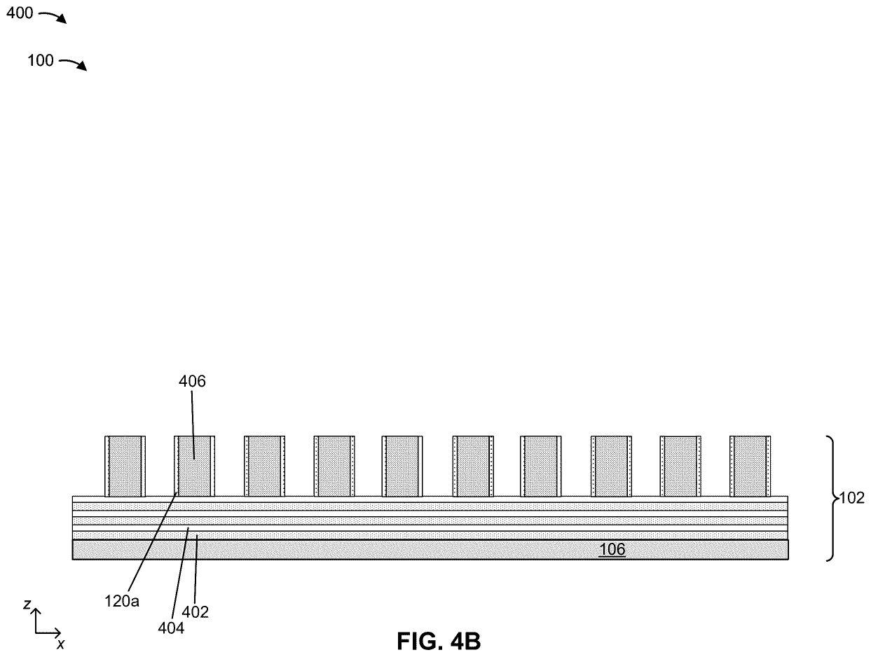

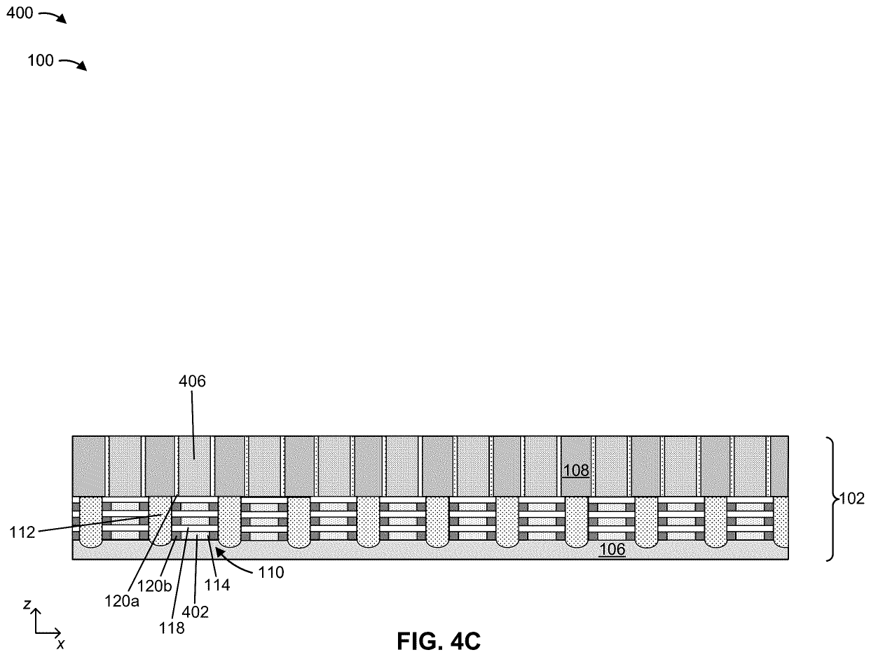

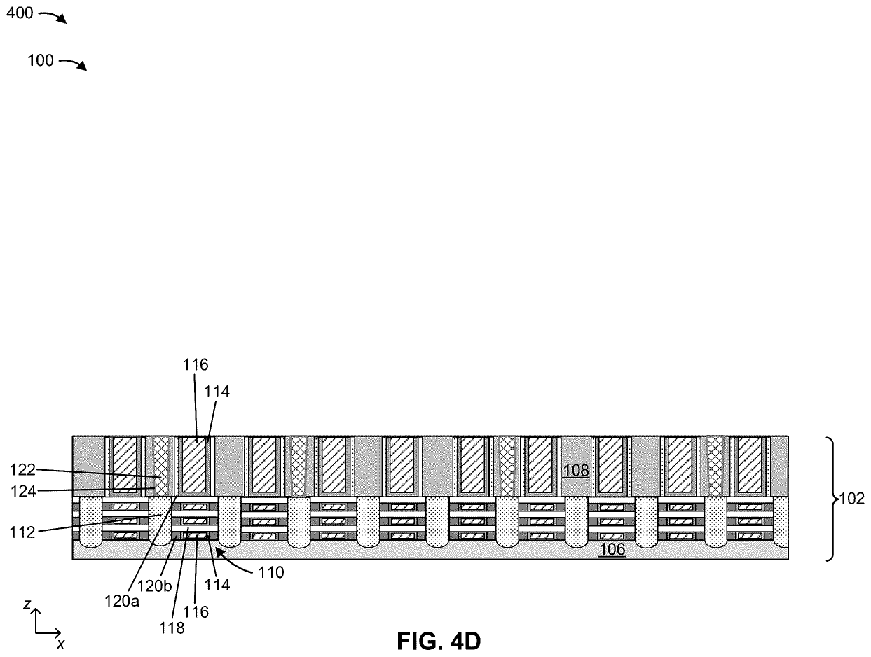

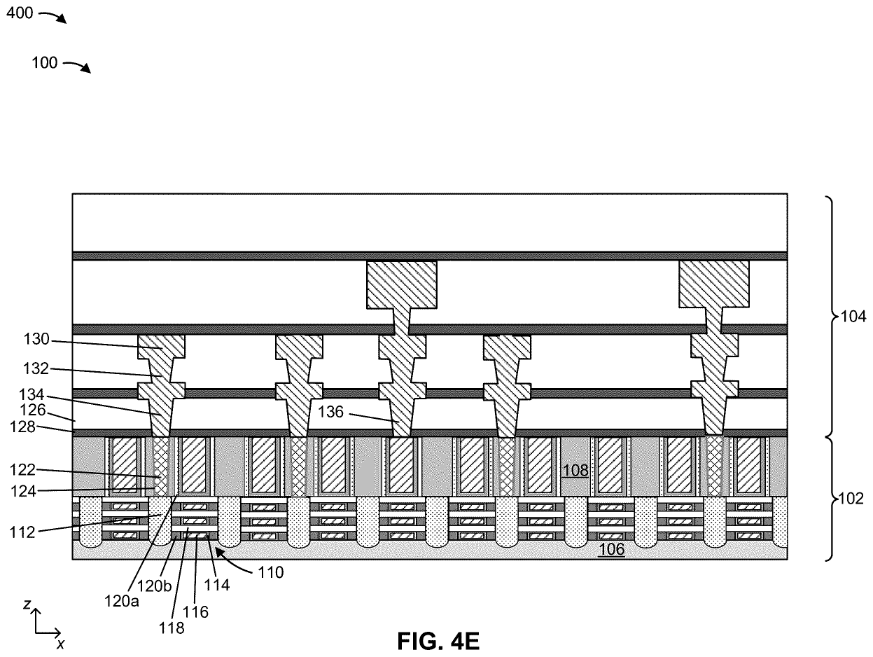

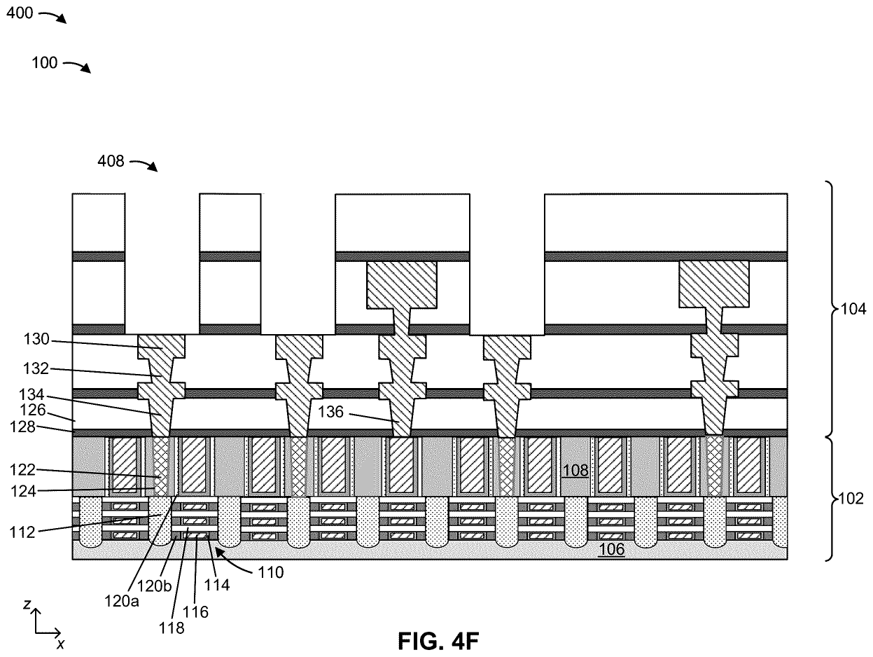

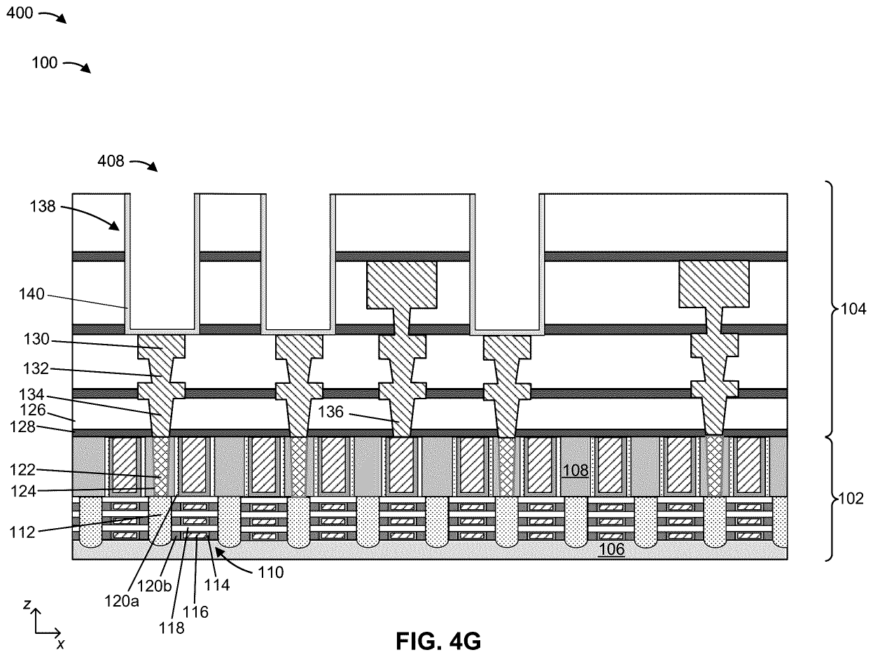

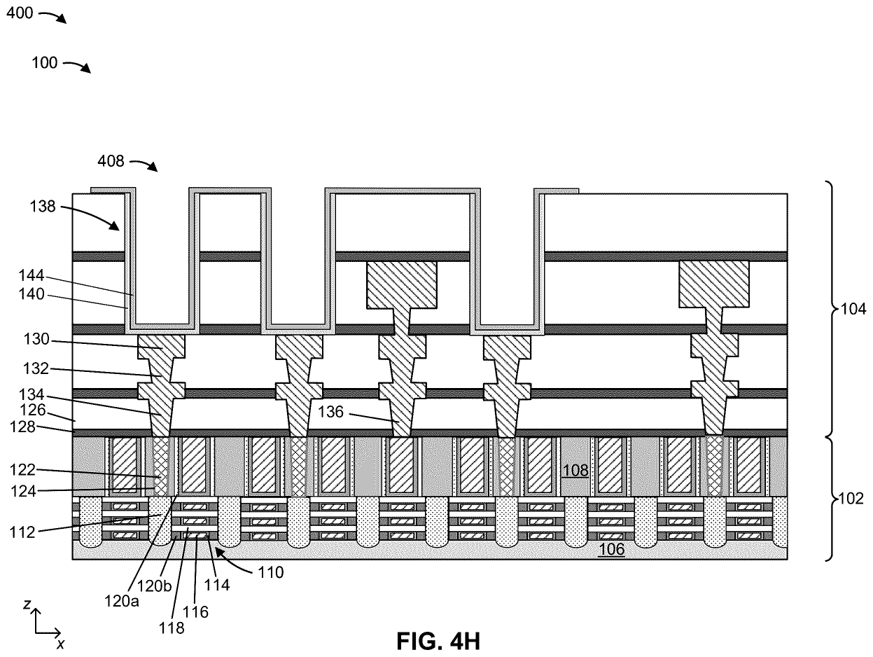

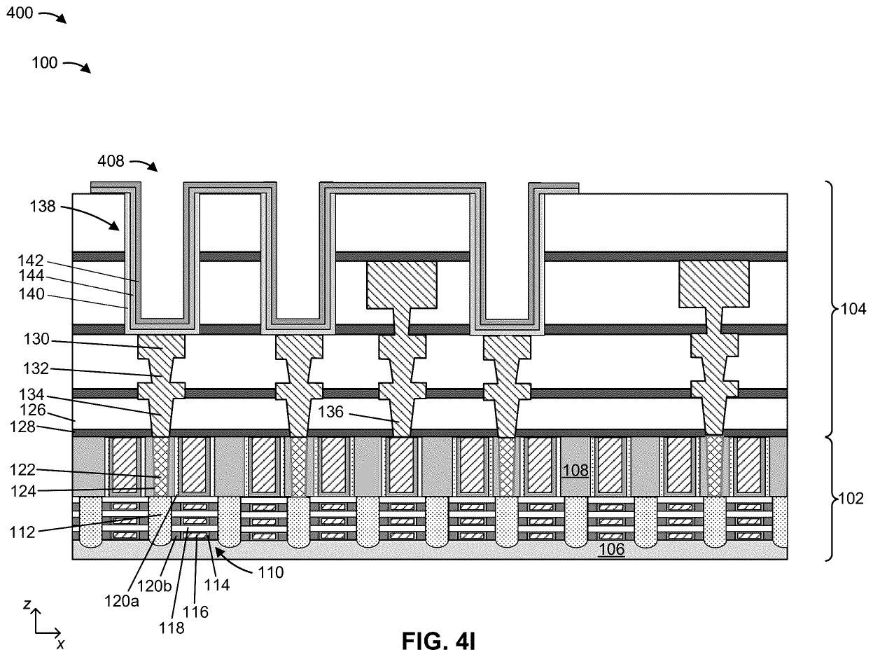

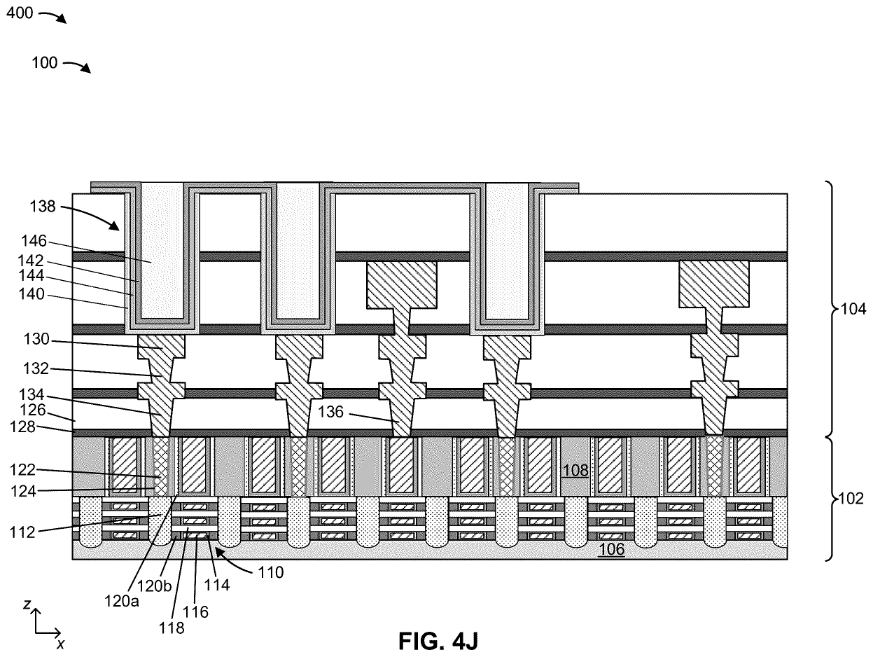

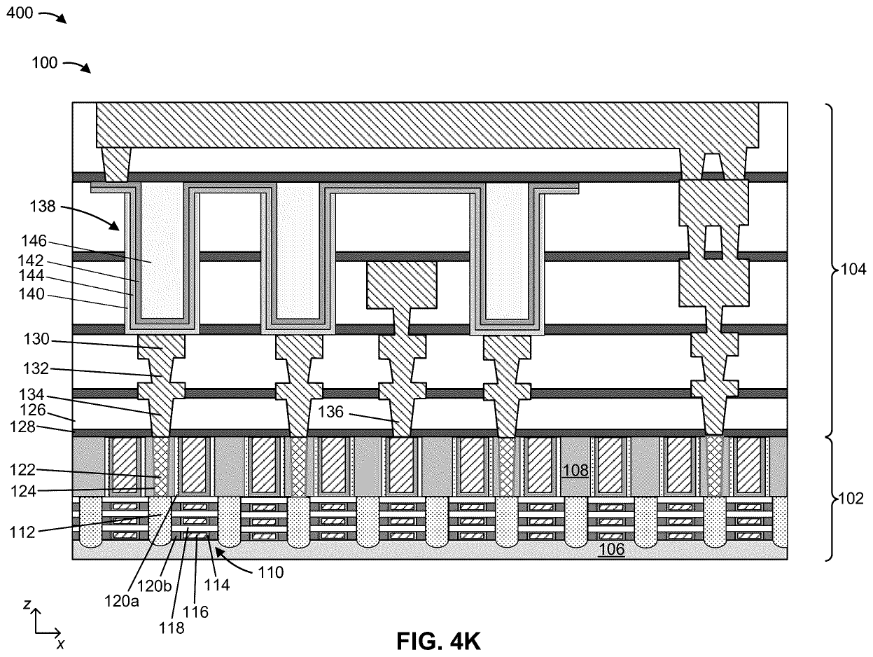

FIGS. 4A-4K are diagrams of an example implementation 400 of forming the semiconductor device 100 described herein. In some implementations, one or more of the semiconductor processing operations described in connection with FIGS. 4A-4K may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 4A, the substrate layer 106 is provided. The substrate layer 106 may be provided in the form of a semiconductor wafer such as a silicon (Si) wafer, a silicon-on-insulator (SOI) wafer, and/or another type of semiconductor work piece. The semiconductor device 100 may be formed on the semiconductor wafer with other semiconductor devices.

As further shown in FIG. 4A, a layer stack may be formed on the substrate layer 106. The layer stack may be referred to as a superlattice. The layer stack may include a plurality of alternating layers that are arranged in a direction (e.g., the z-direction) that is approximately perpendicular to the substrate layer 106. For example, the layer stack may include vertically alternating layers of sacrificial layers 402 and nanostructure channel layers 404 above the substrate layer 106. The quantity of the sacrificial layers 402 and the quantity of the nanostructure channel layers 404 illustrated in FIG. 4A are examples, and other quantities of the sacrificial layers 402 and the nanostructure channel layers 404 are within the scope of the present disclosure.

The sacrificial layers 402 enable a vertical distance to be defined between adjacent nanostructure channels that are formed from the nanostructure channel layers 404, and serve as placeholder layers for subsequently-formed gate structures of the integrated circuit devices 110 of the semiconductor device 100 that are formed around the nanostructure channels.

The sacrificial layers 402 include a first material composition, and the nanostructure channel layers 404 include a second material composition. In some implementations, the first material composition and the second material composition are the same material composition. In some implementations, the first material composition and the second material composition are different material compositions. As an example, the sacrificial layers 402 may include silicon germanium (SiGe) and the nanostructure channel layers 404 may include silicon (Si). This enables the sacrificial layers 402 and/or the nanostructure channel layers 404 to be selectively etched (e.g., enables the sacrificial layers 402 and not the nanostructure channel layers 404 to be etched, enables the nanostructure channel layers 404 and not the sacrificial layers 402 to be etched) depending on the type of etchant that is used.

One or more types of deposition tools may be used to deposit and/or grow the alternating layers of the layer stack to include nanostructures (e.g., nanosheets) on the substrate layer 106. For example, a deposition tool may be used to grow the sacrificial layers 402 and/or the nanostructure channel layers 404 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial layers 402 and/or the nanostructure channel layers 404 may be deposited by chemical vapor deposition (CVD), physical vapor deposition (PVD), atomic layer deposition (ALD), and/or another suitable deposition technique.

In the y-direction, which is not visible in the view in FIG. 4A, the layer stack and the substrate layer 106 may be etched to form fin structures that extend in the x-direction. A fin structure may include a portion of the layer stack and a portion of the substrate layer 106 under the layer stack. The fin structures may be formed by patterning the one or more masking layers and etching based on a pattern formed in one or more of the masking layers. The one or more masking layers may be patterned using photolithography techniques, including double-patterning or multi-patterning techniques. An etch tool may be used to etch the layer stack and the substrate layer 106 based on the pattern using a dry etch technique (e.g., reactive ion etching), a wet etch technique, and/or a combination thereof. In some implementations, shallow trench isolation (STI) regions (not shown) may be formed between adjacent fin structures in the y-direction.

As shown in FIG. 4B, dummy gate structures 406 (also referred to as dummy gate stacks or temporary gate structures) may be formed over portions of the layer stack of sacrificial layers 402 and nanostructure channel layers 404. The dummy gate structures 406 may extend in the y-direction and may be arranged in the x-direction such that the dummy gate structures 406 are approximately perpendicular to the fin structures. The dummy gate structures 406 are sacrificial structures that are to be replaced by replacement gate structures or replacement gate stacks at a subsequent processing stage for the integrated circuit devices 110 of the semiconductor device 100. The dummy gate structures 406 may also be used to define source/drain (S/D) recesses in which source/drain regions of the nanostructure transistors are formed in the layer stack of sacrificial layers 402 and nanostructure channel layers 404.

The dummy gate structures 406 may include polycrystalline silicon (polysilicon or PO) or another material. The layers of the dummy gate structures 406 may be formed using various semiconductor processing techniques such depositing the layers of the dummy gate structures 406 patterning the layers of the dummy gate structures 406 to define the dummy gate structures 406, and/or other semiconductor processing techniques. The sidewall spacers 120a may be formed on the sidewalls of the dummy gate structures 406.

As shown in FIG. 4C, the source/drain regions 112 of the integrated circuit devices 110 are formed in the layer stack of sacrificial layers 402 and nanostructure channel layers 404. To form the source/drain regions 112, source/drain recesses may be formed through the layer stack of sacrificial layers 402 and nanostructure channel layers 404 in an etch operation. The source/drain recesses may be formed on opposing sides of a dummy gate structure 406 in the x-direction. The etch operation may be performed using the etch tool and may be referred to a strained source/drain (SSD) etch operation. In some implementations, the etch operation includes the use of a plasma etch technique, a wet chemical etch technique, and/or another type of etch technique.

Formation of the source/drain recesses may define the channel layers 118. The channel layers 118 may include silicon-based nanostructures (e.g., nanosheets or nanowires, among other examples) that function as the semiconductive channels of the integrated circuit devices 110 of the semiconductor device 100. The channel layers 118 are arranged in a direction (e.g., the z-direction) that is approximately perpendicular to the substrate layer 106. In other words, the channel layers 118 are vertically arranged or stacked above the substrate layer 106.

Prior to formation of the source/drain regions 112 in the source/drain recesses, the ends of the sacrificial layers 402 that are exposed in the source/drain recesses may be laterally etched in an etch operation, thereby forming cavities in the ends of the sacrificial layers 402. The inner spacers 120b may be formed in the cavities. To form the inner spacers 120b, a deposition tool may be used to deposit a layer of dielectric material in the cavities and along the sidewalls and bottom surface of the source/drain recesses. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 120b in the cavities.

After formation of the inner spacers 120b, the source/drain recesses may be filled with one or more layers of epitaxial material to form the source/drain regions 112 in the source/drain recesses. For example, a deposition tool may be used to deposit a buffer region at the bottom of the source/drain recess, and a deposition tool may deposit a source/drain region 112 on the buffer region in the source/drain recess. In some implementations, a deposition tool is used to deposit a capping layer on the source/drain region 112 in the source/drain recess. As another example, a deposition tool may epitaxially grow a first layer of a source/drain region 112 (referred to as an L1) over an associated buffer region (which may be referred to as an L0), and may epitaxially grow a second layer of the source/drain region 112 (referred to as an L2, an L2-1, and/or an L2-2) over the first layer. The first layer may include a lightly doped silicon (e.g., doped with boron (B), phosphorous (P), and/or another dopant), and may be included as shielding layer to reduce short channel effects in the semiconductor device 100 and to reduce dopant extrusion or migration into the channel layers 118. The second layer may include a highly doped silicon or highly doped silicon germanium. The second layer may be included to provide a compressive stress in the source/drain regions 112 to reduce boron loss.

As further shown in FIG. 4C, the dielectric layer 108 may be formed over the source/drain regions 112 and around the dummy gate structures 406. The dielectric layer 108 may fill in areas between the dummy gate structures 406. In some implementations, a contact etch stop layer (CESL) is conformally deposited (e.g., using a deposition tool) over the source/drain regions 112 prior to formation of the dielectric layer 108. The dielectric layer 108 is then formed on the CESL. The CESL may provide a mechanism to stop an etch process when forming source/drain contacts 122 for the source/drain regions 112. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As shown in FIG. 4D, a replacement gate process may be performed to replace the dummy gate structures 406 with the gate structures 116 of the integrated circuit devices 110. A dummy gate removal operation may be performed to remove the dummy gate structures 406 from the semiconductor device 100. The removal of the dummy gate structures 406 leaves behind openings (or recesses) in the dielectric layer 108, and provides access to the underlying sacrificial layers 402. The dummy gate structures 406 may be removed in one or more etch operations. Such etch operations may include a plasma etch technique, a wet chemical etch technique, and/or another type of etch technique.

The replacement gate process may include a nanostructure release operation (e.g., an SiGe release operation). The nanostructure release operation is performed to remove the sacrificial layers 402 (e.g., the silicon germanium layers). This results in openings between the channel layers 118 (e.g., the areas around the channel layers 118). The sacrificial layers 402 may be removed through the spaces that were previously occupied by the dummy gate structures 406. The nanostructure release operation may include the use of an etch tool to perform an etch operation to remove the sacrificial layers 402 based on a difference in etch selectivity between the material of the sacrificial layers 402 and the material of the channel layers 118, and between the material of the sacrificial layers 402 and the material of the inner spacers 120b. The inner spacers 120b may function as etch stop layers in the etch operation to protect the source/drain regions 112 from being etched.

The replacement gate operation includes forming gate dielectric layers 114 and gate structures (e.g., replacement gate structures) 116 of the integrated circuit devices 110 in the openings between the source/drain regions 112 and between the inner spacers 120b. In particular, the gate dielectric layers 114 and the gate structures 116 fill the areas between and around the channel layers 118 that were previously occupied by the sacrificial layers 402 such that the gate structures 116 fully wrap around the channel layers 118 and surround the channel layers 118. This increases control of the channel layers 118, increases drive current for the integrated circuit devices 110, and/or reduces short channel effects (SCEs) for the integrated circuit devices 110, among other examples. The gate structures 116 may also fill in the spaces that were previously occupied by the dummy gate structures 406. Portions of a gate structure 116 are formed in between pairs of channel layers 118 in an alternating vertical arrangement. In other words, the semiconductor device 100 includes one or more vertical stacks of alternating channel layers 118 and portions of a gate structure 116.

As further shown in FIG. 4D, the source/drain contact structures 122 of the integrated circuit devices 110 may be formed through the dielectric layer 108. The source/drain contact structures 122 may be formed in recesses in the dielectric layer 108. In some implementations, a pattern in a photoresist layer is used to etch the dielectric layer 108 to form the recesses. In these implementations, a deposition tool may be used to form the photoresist layer on the dielectric layer 108. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 108 based on a pattern to form the recesses.

The source/drain contact structures 122 may be formed in the recesses such that the source/drain contact structures 122 land on the source/drain regions 112. A deposition tool may be used to deposit the material of the source/drain contact structures 122 in the recesses using a CVD technique, a PVD technique, an ALD technique, an electroplating technique, and/or another suitable deposition technique. The material of the source/drain contact structures 122 may be deposited in one or more deposition operations. In some implementations, a seed layer is first deposited, and the material of the source/drain contact structures 122 is deposited on the seed layer. In some implementations, one or more liner layers 124 are deposited in the recesses, and the source/drain contact structures 122 are deposited on the liner layer(s) 124. In some implementations, a planarization tool is used to perform a planarization operation (e.g., a chemical-mechanical planarization (CMP) operation) to planarize the source/drain contact structures 122 after the source/drain contact structures 122 are deposited such that the tops of the source/drain contact structures 122 are approximately co-planar with the top of the dielectric layer 108.

As shown in FIG. 4E, a first portion of the interconnect layer 104 of the semiconductor device 100 is formed above the device layer 102. One or more deposition tools are used to deposit alternating layers of ILD layers 126 and ESLs 128 in the interconnect layer 104 of the semiconductor device 100. In this way, the ILD layers 126 and ESLs 128 may be arranged in the z-direction in the semiconductor device 100. One or more deposition tools may be used to deposit each of the ILD layers 126 and each of the ESLs 128 using a PVD technique, an ALD technique, a CVD technique, an oxidation technique, and/or another suitable deposition technique. In some implementations, a planarization tool may be used to planarize the ILD layers 126 and/or the ESLs 128 after the ILD layers 126 and/or the ESLs 128 are deposited.

As further shown in FIG. 4E, a plurality of layers of conductive structures may be formed in the dielectric layers of the interconnect layer 104. For example, a deposition tool, an exposure tool, a developer tool, an etch tool, a planarization tool, a plating tool, and/or another semiconductor processing tool may be used to perform various operations to form the source/drain interconnect structures 134 and/or the gate interconnect structures 136 at the bottom of the interconnect layer 104. One or more source/drain interconnect structures 134 may be formed on one or more source/drain contact structures 122 of one or more integrated circuit devices 110. One or more gate interconnect structures 136 may be formed on one or more gate structures 116 of one or more integrated circuit devices 110.

A deposition tool, an exposure tool, a developer tool, an etch tool, a planarization tool, a plating tool, and/or another semiconductor processing tool may be used to perform various operations to form the metallization structures 130 and to form the interconnect structures 132 in the interconnect layer 104 of the semiconductor device 100. In some implementations, the interconnect layer 104 may be formed in a plurality of layers. For example, an ILD layer 126 and an ESL 128 may be formed (e.g., using one or more deposition tools and/or one or more planarization tools), recesses may be formed in and/or through the ILD layer 126 and the ESL 128 (e.g., using an exposure tool, a developer tool, and/or an etch tool), and a layer of metallization structures 130 (e.g., the M0 layer) may be formed in the ILD layer 126 and the ESL 128 (e.g., using one or more deposition tools and/or one or more planarization tools). Another ILD layer 126 and another ESL 128 may be formed, and a layer of interconnect structures 132 120a (e.g., the V1 layer) may be formed in the ILD layer 126 and the ESL 128. Additional layers of metallization structures 130 and additional layers of interconnect structures 132 may be formed in a similar manner.

One or more deposition tools may be used to deposit the source/drain interconnect structures 134, the gate interconnect structures 136, the metallization structures 130, and/or the interconnect structures 132 using a PVD technique, an ALD technique, a CVD technique, an electroplating technique (e.g., an electro-chemical plating technique), and/or another suitable deposition technique. In some implementations, a planarization tool may be used to planarize the source/drain interconnect structures 134, the gate interconnect structures 136, the metallization structures 130, and/or the interconnect structures 132 after the source/drain interconnect structures 134, the gate interconnect structures 136, the metallization structures 130, and/or the interconnect structures 132 are deposited.

As shown in FIG. 4F, one or more recesses 408 may be formed in and/or through one or more of the dielectric layers in the interconnect layer 104, such as one or more ILD layers 126 and/or one or more ESLs 128. A recess 408 may be formed over a conductive structure in the interconnect layer 104, such as over a metallization structure 130. In some implementations, the top of the metallization structure 130 may be exposed at the bottom of the recess 408.

In some implementations, a pattern in a photoresist layer is used to etch the one or more dielectric layers to form the recess(es) 408. In these implementations, a deposition tool may be used to form the photoresist layer on the top-most dielectric layer (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the one or more dielectric layers based on the pattern to form the recess(es) 408. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess(es) 408 based on a pattern.

As shown in FIG. 4G, a bottom electrode layer 140 of a capacitor structure 138 may be conformally deposited on the sidewalls and bottom surface of a recess 408. In some implementations, the bottom electrode layer 140 is deposited on the top surface of a metallization structure 130 at the bottom of the recess 408. The bottom electrode layer 140 may be deposited using a deposition tool, and using a conformal deposition technique such as CVD and/or ALD, among other examples. In some implementations, the bottom electrode layer 140 is formed of a metal material having a high work function and/or having a low hydrogen diffusion coefficient. In some implementations, the bottom electrode layer 140 is formed of another type of metal material.

In some implementations, a plurality of recesses 408 are formed for the capacitor structure 138, and bottom electrode layers 140 are conformally deposited in each of the recesses 408. A deposition tool may be used to deposit a conformal metal layer that continuously spans in and between the plurality of recesses 408, and a planarization tool may be used to subsequently perform a planarization to planarize the metal layer to form non-contiguous bottom electrode layers 140 in recesses 408. In this way, each of the bottom electrode layers 140 is electrically coupled to its own metallization structure 130 at the bottom of a recess 408.

As shown in FIG. 4H, an insulator layer 144 of the capacitor structure 138 may be conformally deposited on the sidewalls and bottom surface of a recess 408 such that the insulator layer 144 is deposited over the bottom electrode layer 140. The insulator layer 144 may be deposited using a deposition tool, and using a conformal deposition technique such as CVD and/or ALD, among other examples.

In some implementations, a plurality of recesses 408 are formed for the capacitor structure 138, the insulator layer 144 is conformally deposited in each of the recesses 408. A deposition tool may be used to deposit the insulator layer 144 as a conformal dielectric layer that continuously spans in and between the plurality of recesses 408.

As shown in FIG. 4I, a top electrode layer 142 of the capacitor structure 138 may be conformally deposited on the sidewalls and bottom surface of a recess 408 such that the top electrode layer 142 is deposited over the insulator layer 144. The top electrode layer 142 may be deposited using a deposition tool, and using a conformal deposition technique such as CVD and/or ALD, among other examples. In some implementations, the top electrode layer 142 is formed of a metal material having a high work function and/or having a low hydrogen diffusion coefficient. In some implementations, the top electrode layer 142 is formed of another type of metal material.

In some implementations, a plurality of recesses 408 are formed for the capacitor structure 138, the top electrode layer 142 is conformally deposited in each of the recesses 408. A deposition tool may be used to deposit the top electrode layer 142 as a conformal metal layer that continuously spans in and between the plurality of recesses 408.

As shown in FIG. 4J, the remaining areas in the recesses 408 may be filled in by depositing dielectric fillers 146 in the recesses 408. A deposition tool may be used to deposit the dielectric fillers 146 using a PVD technique, an ALD technique, a CVD technique, an oxidation technique, and/or another suitable deposition technique. The dielectric fillers 146 may be deposited as a singular layer that is then planarized using a planarization tool to remove excess material of the layer to define the dielectric fillers 146.

As shown in FIG. 4K, additional dielectric layers of the interconnect layer 104 may be formed above and/or over the capacitor structure 138. For example, one or more deposition tools are used to deposit additional alternating layers of ILD layers 126 and ESLs 128 in the interconnect layer 104 of the semiconductor device 100 using a PVD technique, an ALD technique, a CVD technique, an oxidation technique, and/or another suitable deposition technique. In some implementations, a planarization tool may be used to planarize the additional ILD layers 126 and/or the additional ESLs 128.

As further shown in FIG. 4K, additional conductive structures may be formed in the additional dielectric layers above the capacitor structure 138 in the interconnect layer 104. In some implementations, an interconnect structure 132 may be formed above the capacitor structure 138 such that the interconnect structure 132 lands on, and is in electrical and/or physical connection with, the top electrode layer 142 of the capacitor structure 138. A metallization structure 130 may be formed above the interconnect structure 132.

As indicated above, FIGS. 4A-4K are provided as an example. Other examples may differ from what is described with regard to FIGS. 4A-4K.

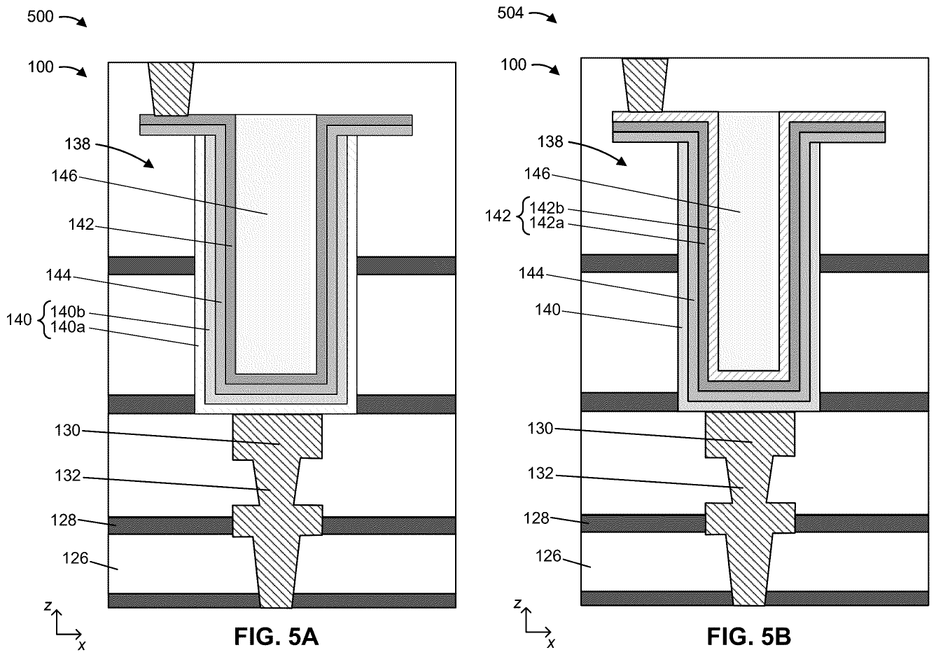

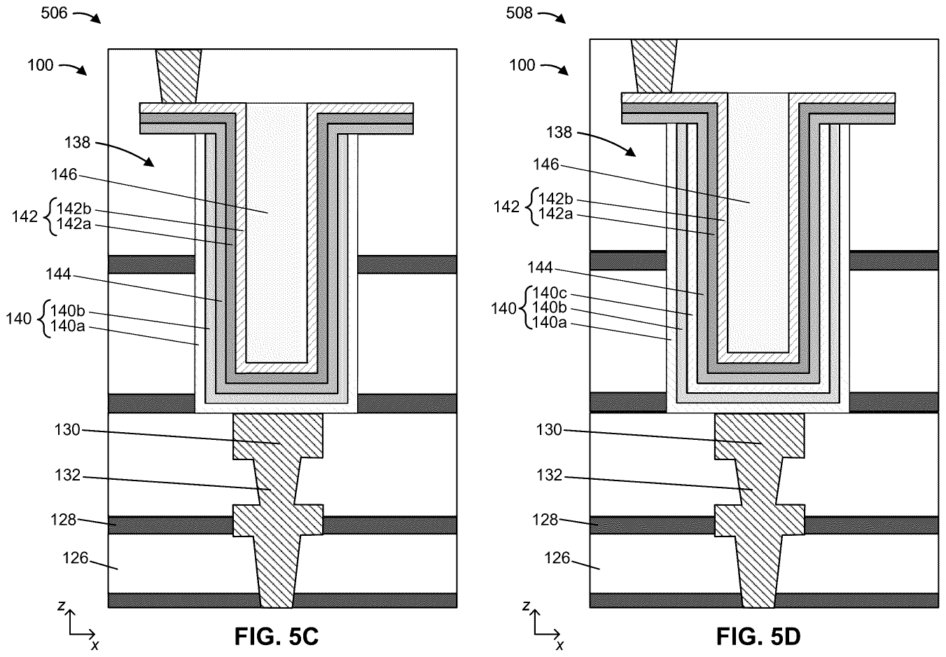

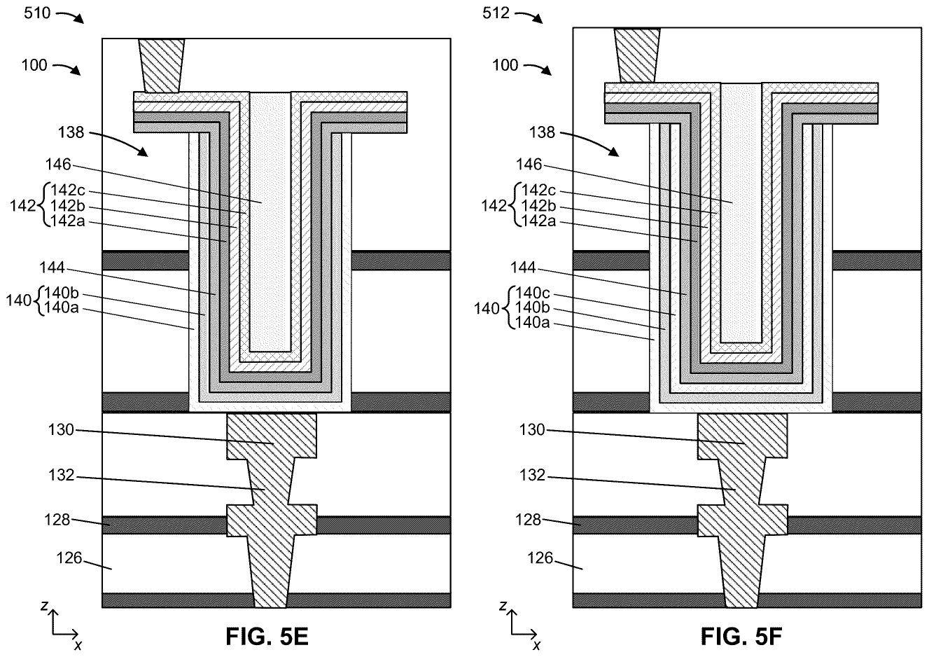

FIGS. 5A-5F are diagrams of example implementations of electrode layer combinations for a capacitor structure 138 described herein. The electrode layer combinations illustrated in FIGS. 5A-5F include various components of single-layer films and/or multiple-layer films for the bottom electrode layer 140 of the capacitor structure 138 and/or for the top electrode layer 142 of the capacitor structure 138. The electrode layer combinations for the capacitor structure 138 may be formed by similar processes as illustrated and described in connection with FIGS. 4A-4K.

FIG. 5A illustrates an example implementation 500 of an electrode layer combination in which the bottom electrode layer 140 of the capacitor structure 138 includes a multiple-layer film and the top electrode layer 142 of the capacitor structure 138 includes a single-layer film. The multiple-layer film enables different layers of the bottom electrode layer 140 to emphasize different properties, such as hydrogen blocking and work function tuning.

For example, the bottom electrode layer 140 may include a metal layer 140a and a metal layer 140b on the metal layer 140a. The metal layer 140a may include a metal material having a low hydrogen diffusion coefficient, whereas the metal layer 140b may include a different metal material having a high work function. The low hydrogen diffusion coefficient metal may be included as the outer layer of the multiple-layer film for blocking hydrogen diffusion, which enables the metal layer 140b to be formed of a high work function metal such as copper (Cu).

In some implementations, the bottom electrode layer 140 may have a well-defined and visible interface between the metal layers 140a and 140b. In some implementations, at least some intermixing of the metal layers 140a and 140b may occur in the bottom electrode layer 140.

In some implementations, the top electrode layer 142 includes titanium (Ti), titanium nitride (TiN), a metal material having a low hydrogen diffusion coefficient, and/or a metal material having a high work function, among other examples. In some implementations, the top electrode layer 142 and the metal layer 140a of the bottom electrode layer 140 contain the same metal material. In some implementations, the top electrode layer 142 and the metal layer 140a of the bottom electrode layer 140 contain different metal materials. In some implementations, the top electrode layer 142 and the metal layer 140b of the bottom electrode layer 140 contain the same metal material. In some implementations, the top electrode layer 142 and the metal layer 140b of the bottom electrode layer 140 contain different metal materials.

FIG. 5B illustrates an example implementation 504 of an electrode layer combination in which the top electrode layer 142 of the capacitor structure 138 includes a multiple-layer film and the bottom electrode layer 140 of the capacitor structure 138 includes a single-layer film. The multiple-layer film enables different layers of the top electrode layer 142 to emphasize different properties, such as hydrogen blocking and work function tuning.

For example, the top electrode layer 142 may include a metal layer 142a and a metal layer 142b on the metal layer 142a. The metal layer 142a may include a metal material having a high work function, whereas the metal layer 142b may include a different metal material having a low hydrogen diffusion coefficient. The low hydrogen diffusion coefficient metal may be included as the outer layer of the multiple-layer film for blocking hydrogen diffusion, which enables the metal layer 142a to be formed of a high work function metal such as copper (Cu).

In some implementations, the top electrode layer 142 may have a well-defined and visible interface between the metal layers 142a and 142b. In some implementations, at least some intermixing of the metal layers 142a and 142b may occur in the top electrode layer 142.

In some implementations, the bottom electrode layer 140 includes titanium (Ti), titanium nitride (TiN), a metal material having a low hydrogen diffusion coefficient, and/or a metal material having a high work function, among other examples. In some implementations, the bottom electrode layer 140 and the metal layer 142a of the top electrode layer 142 contain the same metal material. In some implementations, the bottom electrode layer 140 and the metal layer 142a of the top electrode layer 142 contain different metal materials. In some implementations, the bottom electrode layer 140 and the metal layer 142b of the top electrode layer 142 contain the same metal material. In some implementations, the bottom electrode layer 140 and the metal layer 142b of the top electrode layer 142 contain different metal materials.

FIG. 5C illustrates an example implementation 506 of an electrode layer combination in which the bottom electrode layer 140 of the capacitor structure 138 includes a multiple-layer film and the top electrode layer 142 of the capacitor structure 138 also includes a multiple-layer film. The multiple-layer films enable different layers of the bottom electrode layer 140 and of the top electrode layer 142 to emphasize different properties, such as hydrogen blocking and work function tuning.

For example, the bottom electrode layer 140 may include a metal layer 140a and a metal layer 140b on the metal layer 140a. The metal layer 140a may include a metal material having a low hydrogen diffusion coefficient, whereas the metal layer 140b may include a different metal material having a high work function. The low hydrogen diffusion coefficient metal may be included as the outer layer of the multiple-layer film for blocking hydrogen diffusion, which enables the metal layer 140b to be formed of a high work function metal such as copper (Cu).

The top electrode layer 142 may include a metal layer 142a and a metal layer 142b on the metal layer 142a. The metal layer 142a may include a metal material having a high work function, whereas the metal layer 142b may include a different metal material having a low hydrogen diffusion coefficient. The low hydrogen diffusion coefficient metal may be included as the outer layer of the multiple-layer film for blocking hydrogen diffusion, which enables the metal layer 142a to be formed of a high work function metal such as copper (Cu).

In some implementations, the metal layer 140a of the bottom electrode layer 140 and the metal layer 142a of the top electrode layer 142 contain the same metal material. In some implementations, the metal layer 140a of the bottom electrode layer 140 and the metal layer 142a of the top electrode layer 142 contain different metal materials. In some implementations, the metal layer 140b of the bottom electrode layer 140 and the metal layer 142b of the top electrode layer 142 contain the same metal material. In some implementations, the metal layer 140b of the bottom electrode layer 140 and the metal layer 142b of the top electrode layer 142 contain different metal materials.

In some implementations, the metal layer 140a of the bottom electrode layer 140 and the metal layer 142b of the top electrode layer 142 contain the same metal material. In some implementations, the metal layer 140a of the bottom electrode layer 140 and the metal layer 142b of the top electrode layer 142 contain different metal materials. In some implementations, the metal layer 140b of the bottom electrode layer 140 and the metal layer 142a of the top electrode layer 142 contain the same metal material. In some implementations, the metal layer 140b of the bottom electrode layer 140 and the metal layer 142a of the top electrode layer 142 contain different metal materials.

FIG. 5D illustrates an example implementation 508 of an electrode layer combination in which the bottom electrode layer 140 of the capacitor structure 138 includes a multiple-layer film and the top electrode layer 142 of the capacitor structure 138 also includes a multiple-layer film. The multiple-layer films enable different layers of the bottom electrode layer 140 and of the top electrode layer 142 to emphasize different properties, such as hydrogen blocking and work function tuning.

For example, the bottom electrode layer 140 may include a metal layer 140a, a metal layer 140b on the metal layer 140a, and a metal layer 140c on the metal layer 140b. The metal layer 140a may include a metal material having a low hydrogen diffusion coefficient, the metal layer 140b may include a different metal material such as titanium (Ti) and/or titanium nitride (TiN), and the metal layer 140c may include a different metal material having a high work function. The low hydrogen diffusion coefficient metal may be included as the outer layer of the multiple-layer film for blocking hydrogen diffusion, which enables the metal layer 140b to be formed of a high work function metal such as copper (Cu). The high work function metal being closest to the insulator layer 144 may provide greater impact on the barrier height between the bottom electrode layer 140 and the insulator layer 144 for leakage prevention.

In some implementations, the bottom electrode layer 140 may have a well-defined and visible interface between the metal layers 140a, 140b, and 140c. In some implementations, at least some intermixing of the metal layers 140a, 140b, and 140c may occur in the bottom electrode layer 140.

The top electrode layer 142 may include a metal layer 142a and a metal layer 142b on the metal layer 142a. The metal layer 142a may include a metal material having a high work function, whereas the metal layer 142b may include a different metal material having a low hydrogen diffusion coefficient. The low hydrogen diffusion coefficient metal may be included as the outer layer of the multiple-layer film for blocking hydrogen diffusion, which enables the metal layer 142a to be formed of a high work function metal such as copper (Cu).

In some implementations, the metal layer 140a of the bottom electrode layer 140 and the metal layer 142a of the top electrode layer 142 contain the same metal material. In some implementations, the metal layer 140a of the bottom electrode layer 140 and the metal layer 142a of the top electrode layer 142 contain different metal materials. In some implementations, the metal layer 140b of the bottom electrode layer 140 and the metal layer 142b of the top electrode layer 142 contain the same metal material. In some implementations, the metal layer 140b of the bottom electrode layer 140 and the metal layer 142b of the top electrode layer 142 contain different metal materials.

In some implementations, the metal layer 140a of the bottom electrode layer 140 and the metal layer 142b of the top electrode layer 142 contain the same metal material. In some implementations, the metal layer 140a of the bottom electrode layer 140 and the metal layer 142b of the top electrode layer 142 contain different metal materials. In some implementations, the metal layer 140b of the bottom electrode layer 140 and the metal layer 142a of the top electrode layer 142 contain the same metal material. In some implementations, the metal layer 140b of the bottom electrode layer 140 and the metal layer 142a of the top electrode layer 142 contain different metal materials.

In some implementations, the metal layer 140c of the bottom electrode layer 140 and the metal layer 142a of the top electrode layer 142 contain the same metal material. In some implementations, the metal layer 140c of the bottom electrode layer 140 and the metal layer 142a of the top electrode layer 142 contain different metal materials. In some implementations, the metal layer 140c of the bottom electrode layer 140 and the metal layer 142b of the top electrode layer 142 contain the same metal material. In some implementations, the metal layer 140c of the bottom electrode layer 140 and the metal layer 142b of the top electrode layer 142 contain different metal materials.

FIG. 5E illustrates an example implementation 510 of an electrode layer combination in which the bottom electrode layer 140 of the capacitor structure 138 includes a multiple-layer film and the top electrode layer 142 of the capacitor structure 138 also includes a multiple-layer film. The multiple-layer films enable different layers of the bottom electrode layer 140 and of the top electrode layer 142 to emphasize different properties, such as hydrogen blocking and work function tuning.

For example, the bottom electrode layer 140 may include a metal layer 140a and a metal layer 140b on the metal layer 140a. The metal layer 140a may include a metal material having a low hydrogen diffusion coefficient, and the metal layer 140c may include a different metal material having a high work function. The low hydrogen diffusion coefficient metal may be included as the outer layer of the multiple-layer film for blocking hydrogen diffusion, which enables the metal layer 140b to be formed of a high work function metal such as copper (Cu). The high work function metal being closest to the insulator layer 144 may provide greater impact on the barrier height between the bottom electrode layer 140 and the insulator layer 144 for leakage prevention.

The top electrode layer 142 may include a metal layer 142a, a metal layer 142b on the metal layer 142a, and a metal layer 142c on the metal layer 142b. The metal layer 142a may include a different metal material having a high work function, the metal layer 142b may include a different metal material such as titanium (Ti) and/or titanium nitride (TiN), and the metal layer 142c may include a metal material having a low hydrogen diffusion coefficient. The low hydrogen diffusion coefficient metal may be included as the outer layer of the multiple-layer film for blocking hydrogen diffusion, which enables the metal layer 142a to be formed of a high work function metal such as copper (Cu). The high work function metal being closest to the insulator layer 144 may provide greater impact on the barrier height between the top electrode layer 142 and the insulator layer 144 for leakage prevention.

In some implementations, the bottom electrode layer 140 may have a well-defined and visible interface between the metal layers 140a and 140b. In some implementations, at least some intermixing of the metal layers 140a and 140b may occur in the bottom electrode layer 140.

In some implementations, the top electrode layer 142 may have a well-defined and visible interface between the metal layers 142a, 142b, and 142c. In some implementations, at least some intermixing of the metal layers 142a, 142b, and 142c may occur in the top electrode layer 142.

In some implementations, the metal layer 140a of the bottom electrode layer 140 and the metal layer 142a of the top electrode layer 142 contain the same metal material. In some implementations, the metal layer 140a of the bottom electrode layer 140 and the metal layer 142a of the top electrode layer 142 contain different metal materials. In some implementations, the metal layer 140b of the bottom electrode layer 140 and the metal layer 142b of the top electrode layer 142 contain the same metal material. In some implementations, the metal layer 140b of the bottom electrode layer 140 and the metal layer 142b of the top electrode layer 142 contain different metal materials.

In some implementations, the metal layer 140a of the bottom electrode layer 140 and the metal layer 142b of the top electrode layer 142 contain the same metal material. In some implementations, the metal layer 140a of the bottom electrode layer 140 and the metal layer 142b of the top electrode layer 142 contain different metal materials. In some implementations, the metal layer 140b of the bottom electrode layer 140 and the metal layer 142a of the top electrode layer 142 contain the same metal material. In some implementations, the metal layer 140b of the bottom electrode layer 140 and the metal layer 142a of the top electrode layer 142 contain different metal materials.

In some implementations, the metal layer 142c of the top electrode layer 142 and the metal layer 140a of the bottom electrode layer 140 contain the same metal material. In some implementations, the metal layer 142c of the top electrode layer 142 and the metal layer 140a of the bottom electrode layer 140 contain different metal materials. In some implementations, the metal layer 142c of the top electrode layer 142 and the metal layer 142b of the bottom electrode layer 140 contain the same metal material. In some implementations, the metal layer 142c of the top electrode layer 142 and the metal layer 142b of the top electrode layer 142 contain different metal materials.

FIG. 5F illustrates an example implementation 512 of an electrode layer combination in which the bottom electrode layer 140 of the capacitor structure 138 includes a multiple-layer film and the top electrode layer 142 of the capacitor structure 138 also includes a multiple-layer film. The multiple-layer films enable different layers of the bottom electrode layer 140 and of the top electrode layer 142 to emphasize different properties, such as hydrogen blocking and work function tuning.

For example, the bottom electrode layer 140 may include a metal layer 140a, a metal layer 140b on the metal layer 140a, and a metal layer 140c on the metal layer 140b. The metal layer 140a may include a metal material having a low hydrogen diffusion coefficient, the metal layer 140b may include a different metal material such as titanium (Ti) and/or titanium nitride (TiN), and the metal layer 140c may include a different metal material having a high work function. The low hydrogen diffusion coefficient metal may be included as the outer layer of the multiple-layer film for blocking hydrogen diffusion, which enables the metal layer 140b to be formed of a high work function metal such as copper (Cu). The high work function metal being closest to the insulator layer 144 may provide greater impact on the barrier height between the bottom electrode layer 140 and the insulator layer 144 for leakage prevention.

The top electrode layer 142 may include a metal layer 142a, a metal layer 142b on the metal layer 142a, and a metal layer 142c on the metal layer 142b. The metal layer 142a may include a different metal material having a high work function, the metal layer 142b may include a different metal material such as titanium (Ti) and/or titanium nitride (TiN), and the metal layer 142c may include a metal material having a low hydrogen diffusion coefficient. The low hydrogen diffusion coefficient metal may be included as the outer layer of the multiple-layer film for blocking hydrogen diffusion, which enables the metal layer 142a to be formed of a high work function metal such as copper (Cu). The high work function metal being closest to the insulator layer 144 may provide greater impact on the barrier height between the top electrode layer 142 and the insulator layer 144 for leakage prevention.

In some implementations, the metal layer 140a of the bottom electrode layer 140 and the metal layer 142a of the top electrode layer 142 contain the same metal material. In some implementations, the metal layer 140a of the bottom electrode layer 140 and the metal layer 142a of the top electrode layer 142 contain different metal materials. In some implementations, the metal layer 140b of the bottom electrode layer 140 and the metal layer 142b of the top electrode layer 142 contain the same metal material. In some implementations, the metal layer 140b of the bottom electrode layer 140 and the metal layer 142b of the top electrode layer 142 contain different metal materials. In some implementations, the metal layer 140c of the bottom electrode layer 140 and the metal layer 142c of the top electrode layer 142 contain the same metal material. In some implementations, the metal layer 140c of the bottom electrode layer 140 and the metal layer 142c of the top electrode layer 142 contain different metal materials.

In some implementations, the metal layer 140a of the bottom electrode layer 140 and the metal layer 142b of the top electrode layer 142 contain the same metal material. In some implementations, the metal layer 140a of the bottom electrode layer 140 and the metal layer 142b of the top electrode layer 142 contain different metal materials. In some implementations, the metal layer 140b of the bottom electrode layer 140 and the metal layer 142a of the top electrode layer 142 contain the same metal material. In some implementations, the metal layer 140b of the bottom electrode layer 140 and the metal layer 142a of the top electrode layer 142 contain different metal materials.

In some implementations, the metal layer 140c of the bottom electrode layer 140 and the metal layer 142a of the top electrode layer 142 contain the same metal material. In some implementations, the metal layer 140c of the bottom electrode layer 140 and the metal layer 142a of the top electrode layer 142 contain different metal materials. In some implementations, the metal layer 140c of the bottom electrode layer 140 and the metal layer 142b of the top electrode layer 142 contain the same metal material. In some implementations, the metal layer 140c of the bottom electrode layer 140 and the metal layer 142b of the top electrode layer 142 contain different metal materials.

In some implementations, the metal layer 142c of the top electrode layer 142 and the metal layer 140a of the bottom electrode layer 140 contain the same metal material. In some implementations, the metal layer 142c of the top electrode layer 142 and the metal layer 140a of the bottom electrode layer 140 contain different metal materials. In some implementations, the metal layer 142c of the top electrode layer 142 and the metal layer 142b of the bottom electrode layer 140 contain the same metal material. In some implementations, the metal layer 142c of the top electrode layer 142 and the metal layer 142b of the top electrode layer 142 contain different metal materials.

As indicated above, FIGS. 5A-5F are provided as examples. Other examples may differ from what is described with regard to FIGS. 5A-5F.

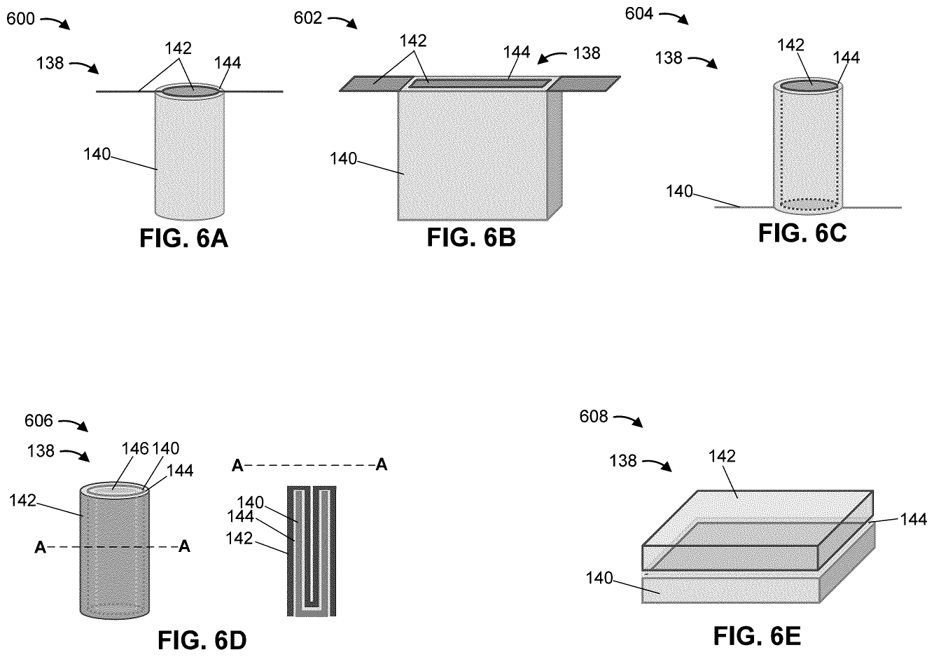

FIGS. 6A-6E are diagrams of example implementations of structural arrangements for a capacitor structure 138 described herein. The example structural arrangements for the capacitor structure 138 may be implemented in the interconnect layer 104 and/or elsewhere in the semiconductor device 100. For the example structural arrangements, the capacitor structure 138 may include one or more of the electrode layer arrangements described herein, and may be formed by similar processes as illustrated and described in connection with FIGS. 4A-4K.

FIG. 6A illustrates an example implementation 600 in which a capacitor structure 138 includes a via structural arrangement. In the via structural arrangement, the bottom electrode layer 140, the top electrode layer 142, and the insulator layer 144 may extend into a via through one or more dielectric layers in the interconnect layer 104. The top electrode layer 142 may extend laterally outward from the top of the via.

FIG. 6B illustrates an example implementation 602 in which a capacitor structure 138 includes a trench structural arrangement. In the trench structural arrangement, the bottom electrode layer 140, the top electrode layer 142, and the insulator layer 144 may extend into a trench through one or more dielectric layers in the interconnect layer 104. The trench may be elongated in one or more lateral directions, as opposed to the via structural arrangement that primarily extends vertically. The top electrode layer 142 may extend laterally outward from the top of the trench.

FIG. 6C illustrates an example implementation 604 in which a capacitor structure 138 includes a pillar structural arrangement. In the pillar structural arrangement, the bottom electrode layer 140, the top electrode layer 142, and the insulator layer 144 may form a pillar that extends from a dielectric layer of the interconnect layer 104. The pillar structural arrangement may be similar to the via structural arrangement, except that the bottom electrode layer 140 may extend laterally outward from the bottom of the pillar.

FIG. 6D illustrates an example implementation 606 in which a capacitor structure 138 includes a cylinder structural arrangement. In the cylinder structural arrangement, the bottom electrode layer 140, the top electrode layer 142, and the insulator layer 144 may form a cylinder that extends from a dielectric layer of the interconnect layer 104. The cylinder structural arrangement may be similar to the pillar structural arrangement, except that the dielectric filler 146 may be included so that the top electrode layer 142 extends along inner and outer walls of the bottom electrode layer 140 in the cylinder structural arrangement, as shown in the cross-section view along line A-A in FIG. 6D.

FIG. 6E illustrates an example implementation 608 in which a capacitor structure 138 includes a planar structural arrangement. In the planar structural arrangement, the bottom electrode layer 140, the top electrode layer 142, and the insulator layer 144 may form a thin-film stack that extends primarily horizontally in the interconnect layer 104.

As indicated above, FIGS. 6A-6E are provided as examples. Other examples may differ from what is described with regard to FIGS. 6A-6E.

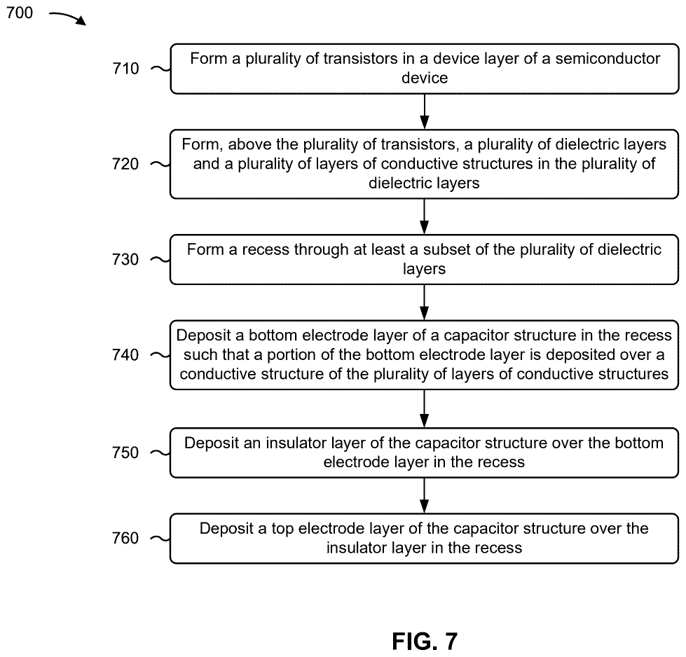

FIG. 7 is a flowchart of an example process 700 associated with forming a semiconductor device described herein. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include forming a plurality of transistors in a device layer of a semiconductor device (block 710). For example, one or more semiconductor processing tools may be used to form a plurality of transistors (e.g., integrated circuit devices 110) in a device layer (e.g., a device layer 102) of a semiconductor device (e.g., of a semiconductor device 100), as described herein.

As further shown in FIG. 7, process 700 may include forming, above the plurality of transistors, a plurality of dielectric layers and a plurality of layers of conductive structures in the plurality of dielectric layers (block 720). For example, one or more semiconductor processing tools may be used to form, above the plurality of transistors, a plurality of dielectric layers (e.g., ILD layers 126, ESLs 128) and a plurality of layers of conductive structures (e.g., metallization structures 130, interconnect structures 132) in the plurality of dielectric layers, as described herein.

As further shown in FIG. 7, process 700 may include forming a recess through at least a subset of the plurality of dielectric layers (block 730). For example, one or more semiconductor processing tools may be used to form a recess (e.g., a recess 408) through at least a subset of the plurality of dielectric layers, as described herein.

As further shown in FIG. 7, process 700 may include depositing a bottom electrode layer of a capacitor structure in the recess such that a portion of the bottom electrode layer is deposited over a conductive structure of the plurality of layers of conductive structures (block 740). For example, one or more semiconductor processing tools may be used to deposit a bottom electrode layer (e.g., a bottom electrode layer 140) of a capacitor structure (e.g., a capacitor structure 138) in the recess such that a portion of the bottom electrode layer is deposited over a conductive structure of the plurality of layers of conductive structures, as described herein. In some implementations, a hydrogen (H) diffusion coefficient of a first metal material of the bottom electrode layer is less than a hydrogen diffusion coefficient of a second metal material of the conductive structure.

As further shown in FIG. 7, process 700 may include depositing an insulator layer of the capacitor structure over the bottom electrode layer in the recess (block 750). For example, one or more semiconductor processing tools may be used to deposit an insulator layer (e.g., an insulator layer 144) of the capacitor structure over the bottom electrode layer in the recess, as described herein.

As further shown in FIG. 7, process 700 may include depositing a top electrode layer of the capacitor structure over the insulator layer in the recess (block 760). For example, one or more semiconductor processing tools may be used to deposit a top electrode layer (e.g., a top electrode layer 142) of the capacitor structure over the insulator layer in the recess, as described herein.

Process 700 may include additional implementations, such as any single implementation or any combination of implementations described below and/or in connection with one or more other processes described elsewhere herein.

In a first implementation, a work function of the first metal material of the bottom electrode layer is greater than a work function of the second metal material of the conductive structure.

In a second implementation, alone or in combination with the first implementation, the second metal material of the conductive structure includes copper (Cu), and the first metal material of the conductive structure includes at least one of ruthenium (Ru), nickeling (Ni), platinum (Pt), or palladium (Pd).

In a third implementation, alone or in combination with one or more of the first and second implementations, depositing the top electrode layer includes depositing a first metal layer (e.g., a metal layer 142a), of a multiple-layer film of the top electrode layer, over the insulator layer, and depositing a second metal layer (e.g., a metal layer 142b), of the multiple-layer film, over the first metal layer, where the first metal layer contains a third metal material, where the second metal layer contains a fourth metal material, and where the third metal material and the fourth metal material are different metal materials.

In a fourth implementation, alone or in combination with one or more of the first through third implementations, the third metal material and the fourth metal material are different than the first metal material and the second metal material.

In a fifth implementation, alone or in combination with one or more of the first through fourth implementations, a work function of the third metal material is greater than the work function of the second metal material, and where a hydrogen diffusion coefficient of the fourth metal material is less than the hydrogen diffusion coefficient of the second metal material.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, a capacitor structure included in a semiconductor device (e.g., an interconnect layer of a semiconductor device) may include one or more electrode layers that contain materials that have low hydrogen absorption properties to achieve a low concentration of hydrogen in the capacitor structure. These materials enable the capacitor structure to be formed by low-temperature processes that are compatible with layers and/or structures of the semiconductor device, while enabling fast charging and discharging speeds to be achieved for the capacitor structure. Additionally and/or alternatively, one or more of the electrode layers of the capacitor structure may contain metal materials for tuning the band gap of the electrode layer(s). For example, the metal materials of the electrode layer(s) may have a high band gap, which reduces the likelihood of (and/or amount of) charge carrier tunneling. This enables a low current leakage to be achieved for the capacitor structure, which enables the capacitor structure to retain charge for longer durations with fewer charge refreshes (which reduces power consumption of the semiconductor device).

As described in greater detail above, some implementations described herein provide a semiconductor device. The semiconductor device includes a device layer. The semiconductor device includes a plurality of transistors in the device layer. The semiconductor device includes an interconnect layer over a plurality of transistors. The interconnect layer includes a plurality of dielectric layers interleaved by a plurality of etch stop layers. The interconnect layer includes a plurality of metallization structures disposed in the plurality of dielectric layers. A first thickness of a first metallization structure, of the plurality of metallization structures, at a bottom of the interconnect layer is less than a second thickness of a second metallization structure, of the plurality of metallization structures, above the first metallization structure. The semiconductor device includes a capacitor structure in one or more of the plurality of dielectric layers of the interconnect layer. The capacitor structure includes a bottom electrode layer coupled to the second metallization structure, a top electrode layer, and an insulator layer between the top electrode layer and the bottom electrode layer. The bottom electrode layer contains a metal material that has a work function that is greater than a work function of titanium (Ti), and that has a hydrogen (H) diffusion coefficient that is less than a hydrogen diffusion coefficient of titanium.

As described in greater detail above, some implementations described herein provide a semiconductor device. The semiconductor device includes a device layer. The semiconductor device includes a plurality of transistors in the device layer. At least one of the plurality of transistors includes a gate structure interfacing at least three sides of a channel layer, and a gate dielectric layer over the channel layer and between the channel layer and the gate structure. The semiconductor device includes an interconnect layer, over a plurality of transistors. The interconnect layer includes a plurality of dielectric layers, and a plurality of layers of metallization structures disposed in the plurality of dielectric layers. The plurality of layers of metallization structures are spaced apart from one another by the plurality of dielectric layers. A dielectric constant of the gate dielectric layer is greater than a dielectric constant of the plurality of dielectric layers. The semiconductor device includes a capacitor structure in one or more of the plurality of dielectric layers of the interconnect layer. The capacitor structure includes a bottom electrode layer coupled to a first metallization structure in the plurality of layers of metallization structures, a top electrode layer coupled to a second metallization structure in the plurality of layers of metallization structures, and an insulator layer between the top electrode layer and the bottom electrode layer. At least one of the bottom electrode layer or the top electrode layer includes a multiple-layer film. The multiple-layer film includes a first metal layer that contains a first metal material, and a second metal layer that contains a second metal material that is different than the first metal material. A hydrogen (H) diffusion coefficient of the first metal material is less than a hydrogen diffusion coefficient of titanium (Ti). A work function of the second metal material is greater than a work function of titanium (Ti).

As described in greater detail above, some implementations described herein provide a method. The method includes forming a plurality of transistors in a device layer of a semiconductor device. The method includes forming, above the plurality of transistors, a plurality of dielectric layers and a plurality of layers of conductive structures in the plurality of dielectric layers. The method includes forming a recess through at least a subset of the plurality of dielectric layers. The method includes depositing a bottom electrode layer of a capacitor structure in the recess such that a portion of the bottom electrode layer is deposited over a conductive structure of the plurality of layers of conductive structures. A hydrogen (H) diffusion coefficient of a first metal material of the bottom electrode layer is less than a hydrogen diffusion coefficient of a second metal material of the conductive structure. The method includes depositing an insulator layer of the capacitor structure over the bottom electrode layer in the recess. The method includes depositing a top electrode layer of the capacitor structure over the insulator layer in the recess.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a device layer;
a plurality of transistors in the device layer;
an interconnect layer, over a plurality of transistors, comprising:
a plurality of dielectric layers interleaved by a plurality of etch stop layers; and
a plurality of metallization structures disposed in the plurality of dielectric layers,
wherein a first thickness of a first metallization structure, of the plurality of metallization structures, at a bottom of the interconnect layer is less than a second thickness of a second metallization structure, of the plurality of metallization structures, above the first metallization structure; and
a capacitor structure, in one or more of the plurality of dielectric layers of the interconnect layer, comprising:
a bottom electrode layer coupled to the second metallization structure,
wherein the bottom electrode layer contains a metal material that has a work function that is greater than a work function of titanium (Ti), and that has a hydrogen (H) diffusion coefficient that is less than a hydrogen diffusion coefficient of titanium;
a top electrode layer; and
an insulator layer between the top electrode layer and the bottom electrode layer.

2. The semiconductor device of claim 1, wherein the top electrode layer is coupled to an interconnect structure above the capacitor structure;
wherein the interconnect structure is coupled to a third metallization structure, of the plurality of metallization structures, above the interconnect structure; and
wherein a third thickness of the third metallization structure is greater than the second thickness of the second metallization structure.

3. The semiconductor device of claim 1, wherein the metal material comprises at least one of:
ruthenium (Ru),
nickel (Ni),
platinum (Pt),
palladium (Pd), or
molybdenum (Mo).

4. The semiconductor device of claim 1, wherein the top electrode layer contains a same metal material as the bottom electrode layer.

5. The semiconductor device of claim 1, wherein the top electrode layer contains a metal material that is different than the metal material of the bottom electrode layer.

6. The semiconductor device of claim 5, wherein the work function of the metal material of the bottom electrode layer is greater than a work function of the metal material of the top electrode layer.

7. The semiconductor device of claim 5, wherein the hydrogen diffusion coefficient of the metal material of the bottom electrode layer is less than a hydrogen diffusion coefficient of the metal material of the top electrode layer.

8. A semiconductor device, comprising:
a device layer;
a plurality of transistors in the device layer,
wherein at least one of the plurality of transistors comprises:
a gate structure interfacing at least three sides of a channel layer; and
a gate dielectric layer over the channel layer and between the channel layer and the gate structure;
an interconnect layer, over a plurality of transistors, comprising:
a plurality of dielectric layers;
a plurality of layers of metallization structures disposed in the plurality of dielectric layers,
wherein the plurality of layers of metallization structures are spaced apart from one another by the plurality of dielectric layers, and
wherein a dielectric constant of the gate dielectric layer is greater than a dielectric constant of the plurality of dielectric layers; and
a capacitor structure, in one or more of the plurality of dielectric layers of the interconnect layer, comprising:
a bottom electrode layer coupled to a first metallization structure in the plurality of layers of metallization structures;
a top electrode layer coupled to a second metallization structure in the plurality of layers of metallization structures; and
an insulator layer between the top electrode layer and the bottom electrode layer,
wherein at least one of the bottom electrode layer or the top electrode layer comprises a multiple-layer film that comprises:
a first metal layer that contains a first metal material; and
a second metal layer that contains a second metal material that is different than the first metal material,
wherein a hydrogen (H) diffusion coefficient of the first metal material is less than a hydrogen diffusion coefficient of titanium (Ti), and
wherein a work function of the second metal material is greater than a work function of titanium (Ti).

9. The semiconductor device of claim 8, wherein the bottom electrode layer comprises the multiple-layer film; and
wherein the first metal layer is between the second metal layer and the first metallization structure.

10. The semiconductor device of claim 9, wherein the multiple-layer film comprises:
a third metal layer that contains a third metal material that is different than the first metal material and the second metal material.

11. The semiconductor device of claim 9, wherein the top electrode layer comprises a third metal material that is different than the first metal material and the second metal material.

12. The semiconductor device of claim 11, wherein the work function of the second metal material is greater than a work function of the third metal material.

13. The semiconductor device of claim 9, wherein the top electrode layer comprises another multiple-layer film that comprises:
a third metal layer that contains a third metal material; and
a fourth metal layer that contains a fourth metal material that is different than the third metal material,
wherein a work function of the third metal material is greater than the work function of titanium,
wherein a hydrogen diffusion coefficient of the fourth metal material is less than the hydrogen diffusion coefficient of titanium, and
wherein the fourth metal layer is between the third metal layer and the second metallization structure.

14. The semiconductor device of claim 13, wherein the third metal material is different than the first metal material and the second metal material; and
wherein the fourth metal material is different than the first metal material and the second metal material.

15. A method, comprising:
forming a plurality of transistors in a device layer of a semiconductor device;
forming, above the plurality of transistors, a plurality of dielectric layers and a plurality of layers of conductive structures in the plurality of dielectric layers;
forming a recess through at least a subset of the plurality of dielectric layers;
depositing a bottom electrode layer of a capacitor structure in the recess such that a portion of the bottom electrode layer is deposited over a conductive structure of the plurality of layers of conductive structures,
wherein a hydrogen (H) diffusion coefficient of a first metal material of the bottom electrode layer is less than a hydrogen diffusion coefficient of a second metal material of the conductive structure;
depositing an insulator layer of the capacitor structure over the bottom electrode layer in the recess; and
depositing a top electrode layer of the capacitor structure over the insulator layer in the recess.

16. The method of claim 15, wherein a work function of the first metal material of the bottom electrode layer is greater than a work function of the second metal material of the conductive structure.

17. The method of claim 15, wherein the second metal material of the conductive structure comprises copper (Cu); and
wherein the first metal material of the conductive structure comprises at least one of:
ruthenium (Ru),
nickel (Ni),
platinum (Pt), or
palladium (Pd).

18. The method of claim 15, wherein depositing the top electrode layer comprises:
depositing a first metal layer, of a multiple-layer film of the top electrode layer, over the insulator layer; and
depositing a second metal layer, of the multiple-layer film, over the first metal layer,
wherein the first metal layer contains a third metal material,
wherein the second metal layer contains a fourth metal material, and
wherein the third metal material and the fourth metal material are different metal materials.

19. The method of claim 18, wherein the third metal material and the fourth metal material are different than the first metal material and the second metal material.

20. The method of claim 18, wherein a work function of the third metal material is greater than the work function of the second metal material; and
wherein a hydrogen diffusion coefficient of the fourth metal material is less than the hydrogen diffusion coefficient of the second metal material.
